(19) United States
(12) Patent Application Publication
(10) Pub. No.: US 2023/0238212 A1
(43) Pub. Date: Jul. 27, 2023

(54) Electron Microscope

(71) Applicant: Hitachi High-Tech Corporation, Minato-ku, Tokyo (JP)

(72) Inventors: Hiroyasu SHICHI, Tokyo (JP); Nobuhiro OKAI, Tokyo (JP); Naomasa SUZUKI, Tokyo (JP); Masanobu IEDA, Tokyo (JP)

(21) Appl. No.: 18/010,939

(22) PCT Filed: Sep. 24, 2021
(86) PCT No.: PCT/JP2021/035071

§ 371 Date: Dec. 16, 2022

(30) Foreign Application Priority Data
Sep. 25, 2020 (WO) PCT/JP2020/036200

(51) Int. Cl. H01J 37/26; H01J 37/285; H01J 37/244

(52) U.S. Cl. CPC H01J 37/268; H01J 37/285; H01J 37/244

(57) ABSTRACT

Provided is an electron microscope for generating an observation image of a sample by using an electron beam in order to obtain a scanning electron microscope image by low angle backscattered electrons, which are backscattered electrons emitted at a low angle with respect to a sample surface, even for an electron microscope including an objective lens that leaks a magnetic field to a sample. The electron microscope includes: an electron source configured to irradiate the sample with the electron beam; an objective lens configured to focus the electron beam by a leakage magnetic field which is a magnetic field leaked toward the sample; a detector configured to detect a third electron which is an electron emitted when a low angle backscattered electron is caused to collide with the sample by the leakage magnetic field, the low angle backscattered electron being a backscattered electron emitted at a low angle with respect to a surface of the sample; and a compensation electrode or a compensation magnetic pole provided between the sample and the detector and configured to control a trajectory of the third electron.

### TECHNICAL FIELD

The present invention relates to an electron microscope.

### BACKGROUND ART

An electron microscope is a device for observing a surface or an inside of a sample in a magnified manner by irradiating the sample with an electron beam. In particular, in a scanning electron microscope, secondary electrons or backscattered electrons emitted from the sample by scanning the sample with the electron beam are used as a luminance signal to obtain an electron microscope image. Therefore, in the scanning electron microscope, an observation image having a higher resolution can be obtained as the electron beam to be emitted is narrowed by using an electrostatic lens or a magnetic lens. In particular, in order to shorten a focal length, a magnetic lens having a magnetic pole structure that leaks a magnetic field toward the sample is used as an objective lens. Such an objective lens is called a semi-in-lens type or a snorkel type because of the shape thereof.

An example of an electron microscope in which a semi-in-lens type objective lens is used will be described. PTL 1 discloses an electron microscope in which secondary electrons emitted from a sample are detected by a detector disposed closer to an electron source than a semi-in-lens. PTL 2 discloses an electron microscope in which a detection efficiency of secondary electrons emitted from a sample is improved by forming an inner surface of a cylindrical member disposed in an objective lens as a surface having a high secondary electron generation efficiency. PTL 3 discloses a scanning electron microscope in which a detection efficiency of secondary electrons can be improved and a signal based on backscattered electrons emitted from a sample can also be detected by providing a surface having a high secondary electron generation efficiency on an inner surface of an inner magnetic pole of an objective lens.

PTL 4 discloses a scanning electron microscope in which a reflection plate for emitting secondary electrons by collision of backscattered electrons is provided in a sample chamber to separate and simultaneously detect secondary electrons and backscattered electrons. PTL 5 discloses that, in order to maintain a detection efficiency even when trajectories of secondary electrons and backscattered electrons change, a voltage applied to an auxiliary electrode extending from a detector toward a sample is controlled based on an inclination of a sample stage and an energy of an electron beam to be emitted.

PTL 6 discloses an electron microscope in which an energy of secondary electrons, backscattered electrons, and the like is identified and detected by controlling trajectories of electrons using a grid electrode disposed in front of a detector. PTL 7 discloses an electron microscope in which secondary electrons emitted from a sample are guided to a detector by applying a voltage to an electrode disposed at a front stage of the detector. Further, PTL 8 discloses an electron microscope in which a positive voltage is applied to a central electrode surrounding a detector with respect to outer electrodes surrounding the central electrode.

### CITATION LIST

### Patent Literature

PTL 1: WO 2011/055520
PTL 2: JP-A-2001-57172
PTL 3: JP-H-11-111211
PTL 4: JP-A-2008-47310
PTL 5: JP-A-2008-210702
PTL 6: JP-A-2010-272525
PTL 7: JP-A-2005-174766
PTL 8: JP-T-2004-503062

### SUMMARY OF INVENTION

### Technical Problem

However, in an electron microscope in which a semi-in-lens is used in any of the patent literature, it is not considered to detect low angle backscattered electrons, which are backscattered electrons emitted at a low angle with respect to a sample surface, to improve an image quality of a backscattered electron image. A magnetic field leaked from the semi-in-lens, which is an objective lens, to narrow an electron beam does not interfere with the detection of the backscattered electrons other than the low angle backscattered electrons, but returns the low angle backscattered electrons to a sample and thus interferes with detection of low angle backscattered electrons. If a detector is too close to a position irradiated with the electron beam to detect the low angle backscattered electrons, the narrowing of the electron beam is adversely affected.

Accordingly, an object of the invention is to provide an electron microscope capable of obtaining a scanning electron microscope image by low angle backscattered electrons, which are backscattered electrons emitted at a low angle with respect to a sample surface, even in an electron microscope including an objective lens that leaks a magnetic field to a sample.

### Solution to Problem

In order to achieve the above object, the invention provides an electron microscope for generating an observation image of a sample using an electron beam. The electron microscope includes: an electron source configured to irradiate the sample with the electron beam; an objective lens configured to focus the electron beam by a leakage magnetic field which is a magnetic field leaked toward the sample; a detector configured to detect a third electron which is an electron emitted when a low angle backscattered electron is caused to collide with the sample by the leakage magnetic field, the low angle backscattered electron being a backscattered electron emitted at a low angle with respect to a surface of the sample; and a compensation electrode or a compensation magnetic pole provided between the sample and the detector and configured to control a trajectory of the third electron.

### Advantageous Effects of Invention

According to the invention, it is possible to provide an electron microscope capable of obtaining a scanning electron microscope image by low angle backscattered electrons, which are backscattered electrons emitted at a low angle with respect to a sample surface, even for an electron microscope including an objective lens that leaks a magnetic field to a sample.

### BRIEF DESCRIPTION OF DRAWINGS

FIG. 1 is a diagram showing an example of an overall configuration of an electron microscope.

FIG. 2A is a side view showing an example of trajectories of low angle electrons emitted from a sample at a low angle.

FIG. 2B is a top view showing an example of trajectories of low angle electrons.

FIG. 2C is a top view showing an example of trajectories of low angle electrons.

FIG. 3 is a side view showing a correlation between an energy of low angle electrons and a point A at which the low angle electrons collide with the sample.

FIG. 4 is a side view showing an example of trajectories of third electrons emitted from the sample due to collision of backscattered electrons with the sample.

FIG. 5A is a side view showing control of a trajectory of third electrons by a compensation electrode.

FIG. 5B is a top view showing the control of the trajectory of the third electrons by the compensation electrode.

FIG. 6 is a diagram showing a correlation between a voltage applied to the compensation electrode and the number of detected third electrons E.

FIG. 7 is a diagram showing an example of a screen according to a first embodiment.

FIG. 8A is a side view showing a compensation electrode and a grid electrode according to a second embodiment.

FIG. 8B is a top view showing the compensation electrode and the grid electrode according to the second embodiment.

FIG. 9A is a side view showing an example of a compensation electrode according to a third embodiment.

FIG. 9B is a top view showing an example of the compensation electrode according to the third embodiment.

FIG. 10 is a diagram showing a correlation between a voltage applied to the compensation electrode according to the third embodiment and the number of detected third electrons E.

FIG. 11A is a side view showing a modification of the compensation electrode according to the third embodiment.

FIG. 11B is a top view showing the modification of the compensation electrode according to the third embodiment.

FIG. 12 is a diagram showing the correlation between the voltage applied to the compensation electrode according to the third embodiment and the number of detected third electrons E.

FIG. 13A is a side view showing the modification of the compensation electrode according to the third embodiment.

FIG. 13B is a top view showing the modification of the compensation electrode according to the third embodiment.

FIG. 14 is a diagram showing a correlation between the voltage applied to the compensation electrode according to the third embodiment and the number of detected third electrons E.

FIG. 15A is a side view showing an example of a compensation electrode according to a fourth embodiment.

FIG. 15B is a top view showing an example of the compensation electrode according to the fourth embodiment.

FIG. 16A is a side view showing a modification of the compensation electrode according to the fourth embodiment.

FIG. 16B is a top view showing the modification of the compensation electrode according to the fourth embodiment.

FIG. 17A is a top view showing an example of a compensation electrode according to a fifth embodiment.

FIG. 17B is a top view showing an example of the compensation electrode according to the fifth embodiment.

FIG. 18A is a side view showing an example of a compensation magnetic pole according to a sixth embodiment.

FIG. 18B is a top view showing an example of the compensation magnetic pole according to the sixth embodiment.

FIG. 19A is a top view showing an example of a compensation electrode according to a seventh embodiment.

FIG. 19B is a top view showing an example of the compensation electrode according to the seventh embodiment.

FIG. 20A is a top view showing an example of a compensation electrode according to an eighth embodiment.

FIG. 20B is a side view showing an example of the compensation electrode according to the eighth embodiment.

FIG. 21 is a cross-sectional view taken along a line FG of FIG. 20A.

FIG. 22A is a top view showing an example of a compensation electrode according to a ninth embodiment.

FIG. 22B is a diagram showing a correlation between a voltage applied to the compensation electrode according to the ninth embodiment and the number of detected third electrons E.

FIG. 23A is a top view showing an example of a compensation electrode according to a 10th embodiment.

FIG. 23B is a top view showing an example of the compensation electrode according to the 10th embodiment.

FIG. 24A is a side view showing an example of the compensation electrode according to the 10th embodiment.

FIG. 24B is a diagram showing a correlation between a voltage applied to the compensation electrode according to the 10th embodiment and the number of detected third electrons E.

FIG. 25A is a top view showing an example of a compensation electrode according to an 11th embodiment.

FIG. 25B is a top view showing an example of the compensation electrode according to the 11th embodiment.

FIG. 26 is a diagram showing a correlation between a voltage applied to the compensation electrode according to the 11th embodiment and the number of detected third electrons E.

FIG. 27 is a top view showing an example of the compensation electrode according to the 11th embodiment.

FIG. 28 is a perspective view showing an example of a compensation electrode according to a 12th embodiment.

FIG. 29A is a side view showing an example of the compensation electrode according to the 12th embodiment.

FIG. 29B is a side view showing an example of the compensation electrode according to the 12th embodiment.

FIG. 30 is a diagram showing a correlation between a voltage applied to the compensation electrode according to the 12th embodiment and the number of detected third electrons E.

FIG. 31 is a perspective view showing an example of a compensation electrode according to a 13th embodiment.

FIG. 32 is a perspective view showing an example of a compensation electrode according to a 14th embodiment.

FIG. 33 is a perspective view showing an example of the compensation electrode according to the 14th embodiment.

FIG. 34A is a diagram showing a scanning electron microscope image obtained by an electron microscope according to the 14th embodiment.

FIG. 34B is a diagram showing the scanning electron microscope image obtained by the electron microscope according to the 14th embodiment.

FIG. 35A is a diagram showing movement of an electron beam obtained by the electron microscope according to the 14th embodiment.

FIG. 35B is a diagram showing the movement of the electron beam obtained by the electron microscope according to the 14th embodiment.

### DESCRIPTION OF EMBODIMENTS

Hereinafter, embodiments of an electron microscope according to the invention will be described with reference to the accompanying drawings. The electron microscope is a device that observes a sample by irradiating the sample with an electron beam.

### First Embodiment

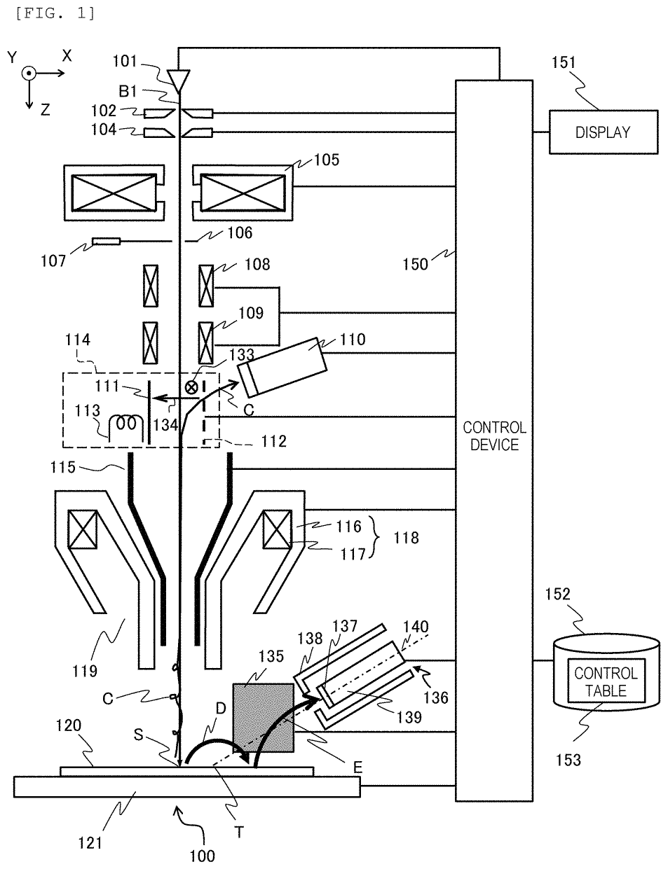

An overall configuration of an electron microscope 100 according to a first embodiment will be described with reference to FIG. 1. A vertical direction is defined as a Z direction, and a horizontal direction is defined as an X direction and a Y direction. The electron microscope 100 includes an electron gun 101, an extraction electrode 102, an anode 104, a condenser lens 105, an aperture 106, an adjustment knob 107, an upper deflector 108, a lower deflector 109, a first detector 110, a Wien filter 114, a pull-up electrode 115, an objective lens 118, a sample stage 121, a compensation electrode 135, a second detector 136, a control device 150, a display 151, and a storage device 152. The control device 150 is a device that controls an operation and the like of each unit, and is, for example, a computer. The storage device 152 stores a control table 153 in which control conditions such as a voltage and a current of each unit are defined. The control device 150 may read the control table 153 from the storage device 152 and control each unit based on the control conditions defined in the control table 153.

The electron gun 101 is an electron source that emits electrons, and is, for example, a field emission cathode. The extraction electrode 102 and the anode 104 are electrodes applied with a positive voltage to the electron gun 101, and each have a hole passed through by a primary electron beam B1, which is electrons emitted from the electron gun 101. An absolute value of the voltage applied to the electron gun 101 is larger in the anode 104 than in the extraction electrode 102. The condenser lens 105 is a lens for focusing the primary electron beam B1. The aperture 106 is a member that determines an opening angle of the primary electron beam B1 in the objective lens 118, and has a hole passed through by the primary electron beam B1. The adjustment knob 107 is used to adjust a center position of the aperture 106. The upper deflector 108 and the lower deflector 109 deflect the primary electron beam B1 and scan a sample 120 with the primary electron beam B1.

The objective lens 118 is a lens for focusing the deflected primary electron beam B1, and includes a magnetic pole 116 and an objective lens coil 117 having a rotationally symmetrical shape. A magnetic field generated by a current flowing through the objective lens coil 117 leaks from a gap 119 of the magnetic pole 116 toward the sample 120 to narrow the primary electron beam B1. That is, the objective lens 118 is a semi-in-lens.

The sample stage 121 holds the sample 120 and controls a position and a posture of the sample 120. That is, the sample stage 121 moves the sample 120 in the horizontal direction or the vertical direction, inclines the sample 120 with respect to a horizontal plane, or rotates the sample 120 with the vertical direction as a rotation axis. A negative voltage is applied to the sample stage 121, and an electric field for decelerating the primary electron beam B1 is formed between the sample 120 on the sample stage 121 and the objective lens 118.

When a point S on the sample 120 is irradiated with the decelerated primary electron beam B1, secondary electrons and backscattered electrons are emitted from the point S. The secondary electrons are, for example, electrons having an energy of less than 100 eV, and the backscattered electrons are, for example, electrons having an energy of 100 eV or more. In addition, the secondary electrons and the backscattered electrons are divided into high angle electrons C emitted at a high angle and low angle electrons D emitted at a low angle with respect to a surface of the sample 120. The electric field for decelerating the primary electron beam B1 pulls up the high angle electrons C into a path of the objective lens 118 while accelerating the high angle electrons C. The high angle electrons C pulled up into the path are affected by the magnetic field of the objective lens 118 and move toward the electron gun 101 while drawing a spiral trajectory. A voltage may be applied to the pull-up electrode 115 provided inside the objective lens 118 so as to pull up more high angle electrons C.

The Wien filter 114 includes an electrode 111, an electrode 112, and a coil 113, and deflects the pulled high angle electrons C toward the first detector 110 by an electric field 134 formed by the electrode 111 and the electrode 112 and a magnetic field 133 formed by the coil 113. The electric field 134 and the magnetic field 133 also act on the primary electron beam B1, but since the actions of the electric field 134 and the magnetic field 133 cancel each other out, the primary electron beam B1 travels straight.

The first detector 110 detects secondary electrons among the high angle electrons C deflected by the Wien filter 114, and transmits a detection signal corresponding to an amount of the detected secondary electrons to the control device 150. The control device 150 generates a secondary electron image based on the received detection signal. The generated secondary electron image is displayed on the display 151 or stored in the storage device 152.

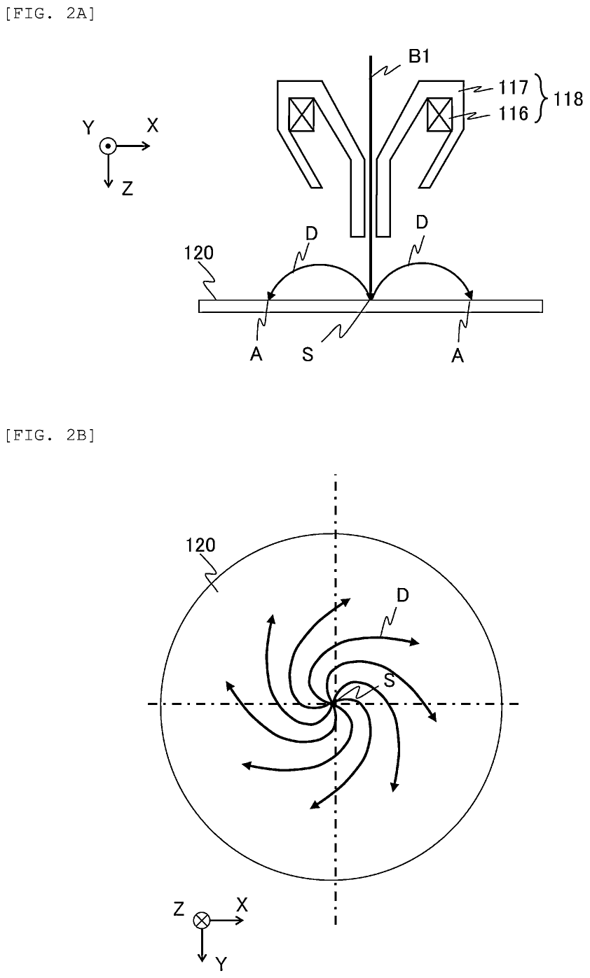

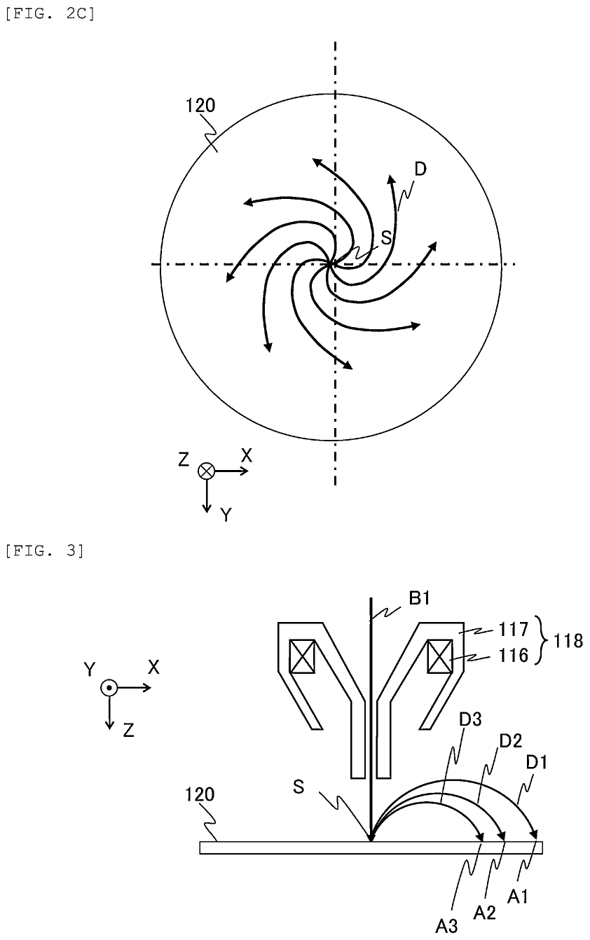

Trajectories of the low angle electrons D emitted from the point S will be described with reference to FIGS. 2A, 2B, and 2C. FIG. 2A is a side view of the objective lens 118 and the sample 120, and FIGS. 2B and 2C are top views of the sample 120 viewed from the electron gun 101. The low angle electrons D are emitted in all directions around a specular reflection direction with respect to the primary electron beam B1, and are pulled back to the sample 120 and collide with the sample 120 as shown in FIG. 2A by a leakage magnetic field which is a magnetic field leaking from the objective lens 118. A distance from the point S to points A at which the low angle electrons D collide with the sample 120 depends on an energy and an elevation angle of the low angle electrons D and an intensity of the leakage magnetic field. In addition, as shown in FIGS. 2B and 2C, each of the low angle electrons D emitted in all directions draws a rotation trajectory around the point S. A direction of the rotation trajectory depends on a direction of the leakage magnetic field, and when a direction of the magnetic field is reversed, the direction of the rotation trajectory of the low angle electrons D is also reversed. That is, in FIGS. 2B and 2C, a direction of the current flowing through the objective lens coil 117 is reversed, and the direction of the leaking magnetic field is also reversed.

A correlation between the distance from the point S to the point A at which the low angle electrons D collide with the sample 120 and the energy of the low angle electrons D will be described with reference to FIG. 3. FIG. 3 shows trajectories of three low angle electrons D1, D2, and D3 having different energies. The distance from the point S to the point A depends on the energy and the elevation angle of the low angle electrons D and the intensity of the leakage magnetic field. A higher energy and a lower intensity of the magnetic field result in a longer distance. That is, as shown in FIG. 3, a point A1 at which low angle electrons D1 having the highest energy collide with the sample 120 is farthest from the point S, and a point A3 at which low angle electrons D3 having the lowest energy collide with the sample 120 is closest to the point S. Since the low angle electrons D are emitted in all directions and values of the energy and the elevation angle have widths, the points A at which the low angle electrons D collide with the sample 120 are distributed in an annular region centered on the point S.

A detector brought close to the point S, which is a position irradiated with the primary electron beam B1 to detect the low angle electrons D in the trajectories shown in FIGS. 2A, 2B, 2C, and 3 adversely affects the narrowing of the primary electron beam B1. Therefore, in the first embodiment, instead of detecting the low angle electrons D, secondary electrons emitted from the sample 120 when the low angle electrons D collide with the sample 120 are detected. In the first embodiment, the secondary electrons emitted when the low angle electrons D collide with the sample 120 are referred to as third electrons E, and are distinguished from the secondary electrons emitted from the point S.

The third electrons E are electrons emitted by backscattered electrons having a relatively high energy among the low angle electrons D. An amount of the third electrons E is proportional to an amount of low angle backscattered electrons, which are the backscattered electrons among the low angle electrons D. Although the amount of the third electrons E also depends on a state of the positions where the low angle electrons D collide, since the points A where the low angle electrons D collide is distributed in the annular region centered on the point S, the influence of the state of the positions where the low angle electrons D collide is reduced. That is, an image generated based on the intensity of the detection signal obtained by detecting the third electrons E is a low angle backscattered electron image. When the third electrons generated from a wide annular region of the sample are detected, it is considered that the third electrons become noise and make it difficult to obtain a clear backscattered electron image, but the inventors have found by calculation and experiments that the primary electron beam can obtain a backscattered electron image in which an irradiated structure can be sufficiently recognized. Since the secondary electrons having a relatively low energy among the low angle electrons D do not contribute to the emission of the third electrons E, the low angle electrons D are interpreted as the low angle backscattered electrons D in the following description.

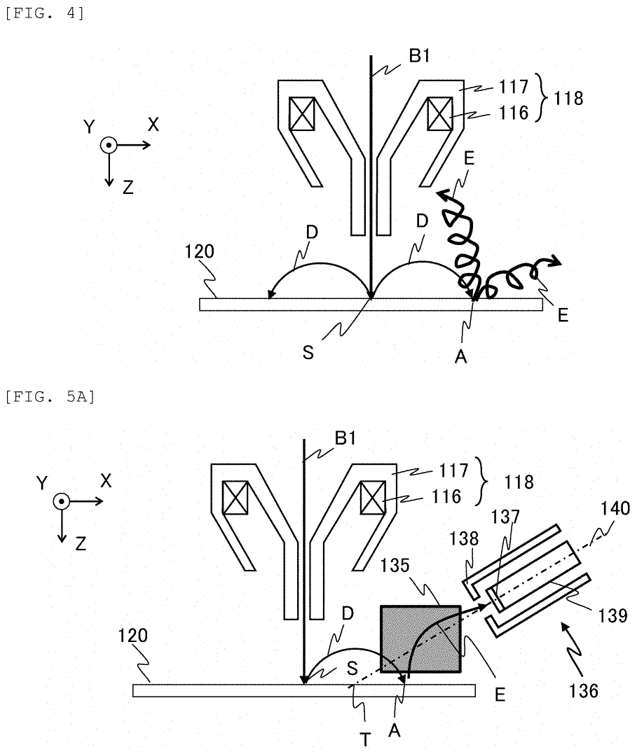

The trajectories of the third electrons E emitted from the points A at which the low angle backscattered electrons D collide with the sample 120 will be described with reference to FIG. 4. The third electrons E have an energy of several eV, are emitted in all directions around a specular reflection direction of a direction in which the low angle backscattered electrons D are incident on the sample 120, and draw spiral trajectories by the leakage magnetic field. Therefore, in the first embodiment, a detector for detecting the third electrons E is disposed at a position away from the point S, and an electrode for superimposing an electric field for controlling the trajectories of the third electrons E toward the detector for detecting the third electrons E is provided in a space where the magnetic field leaked from the objective lens exists.

The description returns to FIG. 1. The second detector 136 is a detector that detects the third electrons E, and includes a fluorescent plate 137, a cover 138, and a photo-multiplier tube 139. The fluorescent plate 137 is a flat plate that emits light upon incidence of the third electrons E, and is a detection surface of the second detector 136. The cover 138 is a metal member that forms an electric field guiding the third electrons E to the fluorescent plate 137. The photo-multiplier tube 139 outputs an electric signal obtained by amplifying photoelectrons generated by light emission of the fluorescent plate 137. That is, the second detector 136 transmits, to the control device 150, a detection signal corresponding to the amount of the third electrons E incident on the fluorescent plate 137. The second detector 136 is disposed at a position sufficiently away from the point S irradiated with the primary electron beam B1, for example, outside the outermost diameter of the objective lens 118. In addition, the direction of the second detector 136 is determined so as to improve a detection efficiency of the third electrons E. For example, the second detector 136 is disposed such that a point T is away from the point S and approaches the second detector 136. The point T is a point at which a center line 140 of the second detector 136, that is, a line passing through a center of the fluorescent plate 137 and orthogonal to the fluorescent plate 137 intersects with the surface of the sample 120. The compensation electrode 135 is an electrode provided between the point S irradiated with the primary electron beam B1 and the second detector 136, and forms the electric field for controlling the trajectories of the third electrons E in the space where the magnetic field leaked from the objective lens exists. The center line 140 of the second detector 136 substantially overlaps a center line of a cylinder which is a shape of the photo-multiplier tube.

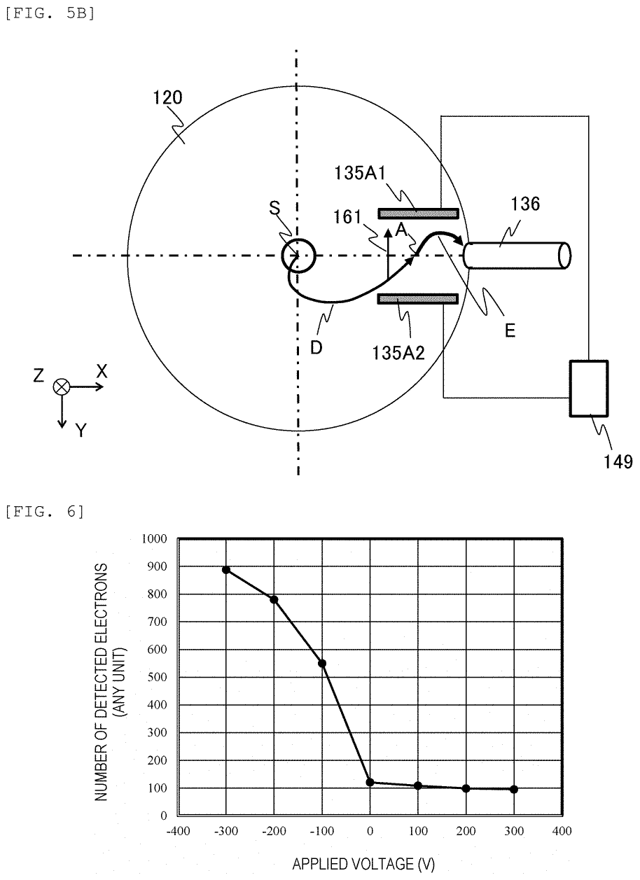

The control of the trajectories of the third electrons E by the compensation electrode 135 in the space where the magnetic field leaked from the objective lens exists will be described with reference to FIGS. 5A and 5B. FIG. 5A is a side view, and FIG. 5B is a top view seen from the electron gun 101. In addition, FIGS. 5A and 5B show only one trajectory of electrons among the low angle backscattered electrons D emitted from the point S in all directions.

The compensation electrode 135 according to the first embodiment is implemented with an electrode 135A1 and an electrode 135A2 which are flat plates parallel to each other, and is applied with a voltage from a voltage source 149. When the electrode 135A1 and the electrode 135A2 disposed substantially perpendicular to the surface of the sample 120 and the fluorescent plate 137 are applied with voltages having opposite polarities and equal absolute values, an electric field is formed in a direction of an arrow 161 substantially parallel to the surface of the sample 120 and the fluorescent plate 137. By adjusting the voltage applied to the compensation electrode 135, a proportion of those detected by the second detector 136 among the third electrons E emitted from the points A can be controlled.

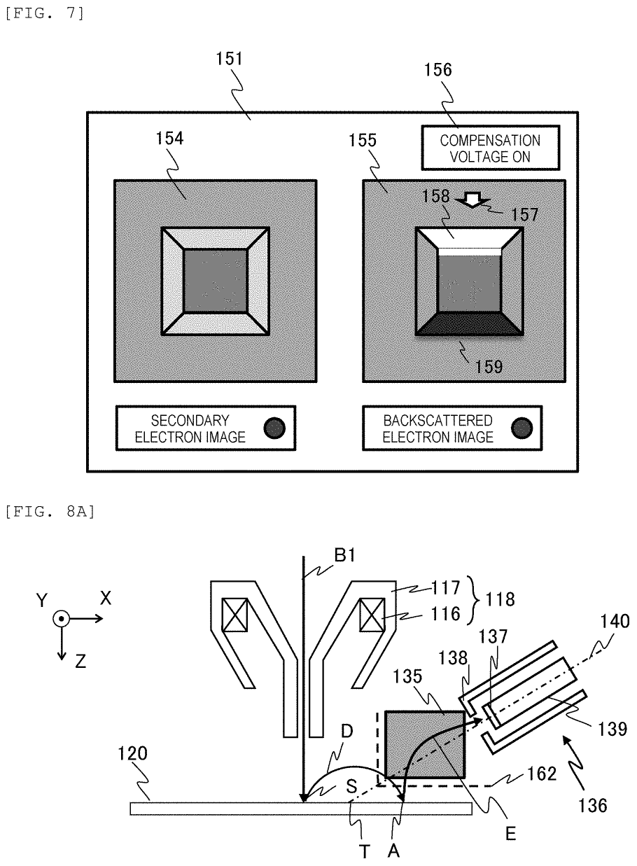

An example of a correlation between the voltage applied to the compensation electrode 135 and the number of the third electrons E detected by the second detector 136 will be described with reference to FIG. 6. FIG. 6 shows a correlation obtained by electron trajectory analysis. A horizontal axis represents the voltage applied to the electrode 135A1, and a vertical axis represents the number of the third electrons E detected by the second detector 136. The voltage having a polarity opposite to that of the voltage applied to the electrode 135A1 is applied to the electrode 135A2.

According to FIG. 6, the number of detected third electrons E is small when a positive voltage is applied to the electrode 135A1, and the number of detected third electrons E increases as a negative voltage is applied to the electrode 135A1 and the absolute value increases. When a negative voltage is applied to the electrode 135A1, an electric field is formed between the electrode 135A1 and the electrode 135A2 in the direction of the arrow 161 in FIG. 5B. The electric field in the direction of the arrow 161 acts to prevent the rotation of the low angle backscattered electrons D around the point S due to the leakage magnetic field.

The description returns to FIG. 5B. Although the third electrons E emitted from the point A temporarily approach the electrode A1, the trajectory of the third electrons E is controlled so as to be directed to the second detector 136 by the electric field in the direction of the arrow 161. That is, the proportion of the third electrons E detected by the second detector 136 can be controlled by adjusting the intensity of the electric field formed between the electrode 135A1 and the electrode 135A2 in the space where the magnetic field leaked from the objective lens exists. Electrons detected by the second detector 136 are not limited to the third electrons E, and may include secondary electrons and backscattered electrons emitted from the point S, backscattered electrons emitted from the points A, and the like. However, the main element of the electrons detected by the second detector 136 is the third electrons E, and the amounts of the secondary electrons and the backscattered electrons emitted from the point S and the backscattered electrons emitted from the points A are smaller than the amount of the third electrons E.

In addition, in the configuration of FIG. 5B, the low angle backscattered electrons D emitted in a specific direction among all directions collide with the sample 120, and the emitted third electrons E are detected. Therefore, the generated low angle backscattered electron image is an image having a limited orientation.

Since the third electrons E are not emitted when the points A with which the low angle backscattered electrons D collide are located at positions deviated from the sample 120 or the sample stage 121, it is desirable that the sample 120 or the sample stage 121 have a size including the annular region in which the points A are distributed. An outer diameter of the annular region depends on the intensity of the leakage magnetic field, and is, for example, about 200 mm in the case of the objective lens 118 used in the electron microscope 100 having an image resolution of several nm. That is, when the image resolution of the electron microscope 100 is several nm, it is desirable that the sample 120 or the sample stage 121 have a diameter of 200 mm or more. A shape of the sample 120 or the sample stage 121 is not limited to a circle, and may be any shape such as a rectangle.

In addition, it is desirable that the direction of the electric field formed between the electrode 135A1 and the electrode 135A2 is set according to the direction of the leakage magnetic field. That is, as shown in FIG. 2C and FIG. 5B, when the low angle backscattered electrons D rotate counterclockwise, the electric field is formed in the direction of the arrow 161 in FIG. 5B, and as shown in FIG. 2B, when the low angle backscattered electrons D rotate clockwise, the electric field is formed in the opposite direction. In other words, it is desirable that an electric field in a direction in which the rotation of the low angle backscattered electrons D due to the leakage magnetic field is prevented is formed by the compensation electrode 135. That is, by superimposing the electric field formed by the compensation electrode 135 on the leakage magnetic field of the objective lens, the third electrons are guided to the second detector 136.

In addition, since the third electrons E emitted from the points A fly in the vicinity of the surface of the sample 120, it is desirable that the compensation electrode 135 is disposed in the vicinity of the surface of the sample 120. In order to avoid collision with the sample 120, a distance between the sample 120 and the compensation electrode 135 may be equal to a distance between the sample 120 and the objective lens 118, for example. Further, since the trajectories of the third electrons E are controlled by the electric field formed by the compensation electrode 135, it is desirable that the surface of the compensation electrode 135 facing the sample 120 is parallel to the surface of the sample 120. With such a structure, it is possible to form an electric field that widely covers a region where the third electrons E fly, and it is easy to control the trajectories of the third electrons E.

The number of electrodes forming the compensation electrode 135 is not limited to two, and may be three or more, and the voltage applied to each electrode may be adjusted such that the value of the detection signal output from the second detector 136 is larger. In addition, an angle between the center line 140 of the second detector 136 and the surface of the sample 120 may be adjusted such that the value of the detection signal output from the second detector 136 is larger.

An example of a screen displayed on the display 151 will be described with reference to FIG. 7. On the screen shown in FIG. 7, an indicator 156 is displayed together with a secondary electron image 154 and a backscattered electron image 155. The secondary electron image 154 is an image generated based on the detection signal transmitted from the first detector 110, and the backscattered electron image 155 is an image generated based on the detection signal transmitted from the second detector 136. The indicator 156 indicates whether a voltage is applied to the compensation electrode 135, and FIG. 7 shows a case where a voltage is applied.

In many cases, the secondary electron image 154 is an image in which details of the sample 120 are easily observed because a signal to noise ratio (SNR) is high, but is also an image in which unevenness of the sample 120 is difficult to recognize. On the other hand, the backscattered electron image 155 is an image whose direction is limited, and thus is an image including a bright line 158 indicating an end portion of a structure and a shadow 159 generated in the vicinity of the structure as if light is applied from an illumination direction 157. That is, an image in which the unevenness of the sample 120 is easily recognized is obtained.

As described above, by superimposing the electric field formed by the compensation electrode 135 in the space where the magnetic field leaked from the semi-in-lens, which is the objective lens, exists, the third electrons E emitted from the points A at which the low angle backscattered electrons D collide with the sample 120 are controlled so as to be directed toward the second detector 136, and thus the third electrons E can be detected by the second detector 136. Since the amount of the third electrons E is proportional to the amount of the low angle backscattered electrons emitted from the point S irradiated with the electron beam, the low angle backscattered electron image can be generated based on the detection signal of the second detector 136. The second detector 136 is disposed at a position that does not adversely affect the narrowing of the primary electron beam B1, and the compensation electrode 135 is provided between the point A and the second detector 136.

That is, according to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, it is possible to obtain an image in which unevenness is more easily recognized than in the related art.

### Second Embodiment

In the first embodiment, the case is described in which the compensation electrode 135 provided between the second detector 136 and the point A, at which the low angle backscattered electrons D collide with the sample 120, is implemented with the electrode 135A1 and the electrode 135A2 parallel to each other. In a second embodiment, a case where a grid electrode is provided together with the compensation electrode 135 including the electrode 135A1 and the electrode 135A2 will be described. Since some of the configurations and functions described in the first embodiment can be applied to the second embodiment, the same reference numerals are used for the same configurations and functions, and the description thereof will be omitted.

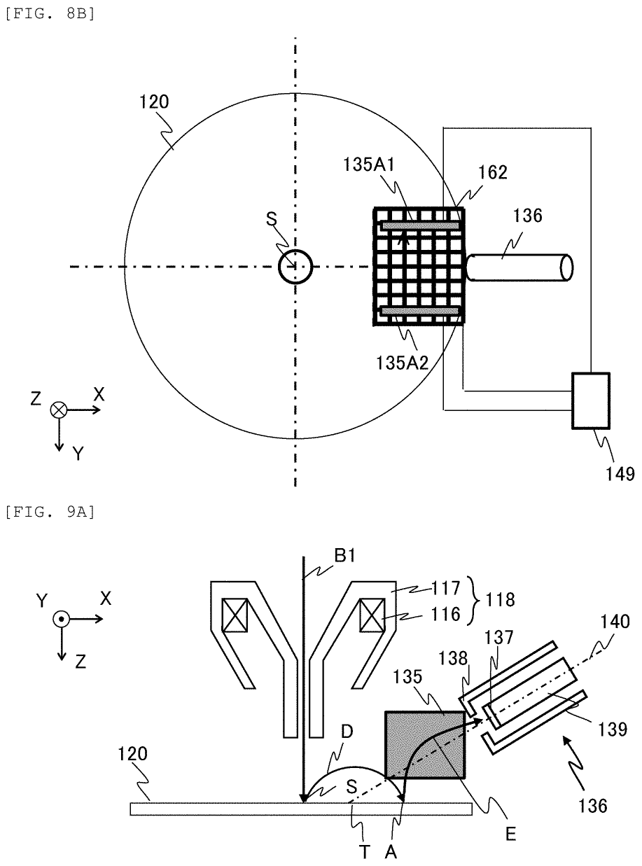

The compensation electrode 135 and a grid electrode 162 according to the second embodiment will be described with reference to FIGS. 8A and 8B. FIG. 8A is a side view, and FIG. 8B is a top view seen from the electron gun 101. As in the first embodiment, the compensation electrode 135 is implemented with the electrode 135A1 and the electrode 135A2 parallel to each other, and is provided between the second detector 136 and the point A, at which the low angle backscattered electrons D collide with the sample 120.

The grid electrode 162 is an electrode in which metal wires are assembled in a lattice shape, and is provided between the compensation electrode 135 and the point S irradiated with the primary electron beam B1. Instead of the grid electrode 162, an electrode implemented with a thin metal plate having a plurality of openings through which electrons pass may be used. The grid electrode 162 has a ground potential, and prevents an electric field formed by the compensation electrode 135 from deflecting the primary electron beam B1. As a result, an increase in a beam diameter of the primary electron beam B1 due to deflection aberration is prevented, and the resolution of the electron microscope can be maintained. The third electrons E emitted from the point A pass through the grid electrode 162, fly while receiving a force from the electric field formed by the compensation electrode 135 and the leakage magnetic field, and are incident on the second detector 136 to be detected.

In addition, in order to increase the amount of the third electrons E passing through the grid electrode 162, a voltage of several volts may be applied to the grid electrode 162. By increasing the amount of the third electrons E passing through the grid electrode 162, a detection efficiency of the second detector 136 is improved, and a backscattered electron image having a high SNR can be obtained.

According to the second embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, the grid electrode 162 can prevent an increase in the beam diameter of the primary electron beam B1 and improve the detection efficiency of the second detector 136, thereby improving an image quality of the backscattered electron image.

### Third Embodiment

In the first embodiment, the case is described in which the compensation electrode 135 provided between the second detector 136 and the point A, at which the low angle backscattered electrons D collide with the sample 120, is implemented with the electrode 135A1 and the electrode 135A2 parallel to each other. In a third embodiment, a case where the compensation electrode 135 is implemented with one of the electrode 135A1 and the electrode 135A2 will be described. Since some of the configurations and functions described in the first embodiment can be applied to the third embodiment, the same reference numerals are used for the same configurations and functions, and the description thereof will be omitted.

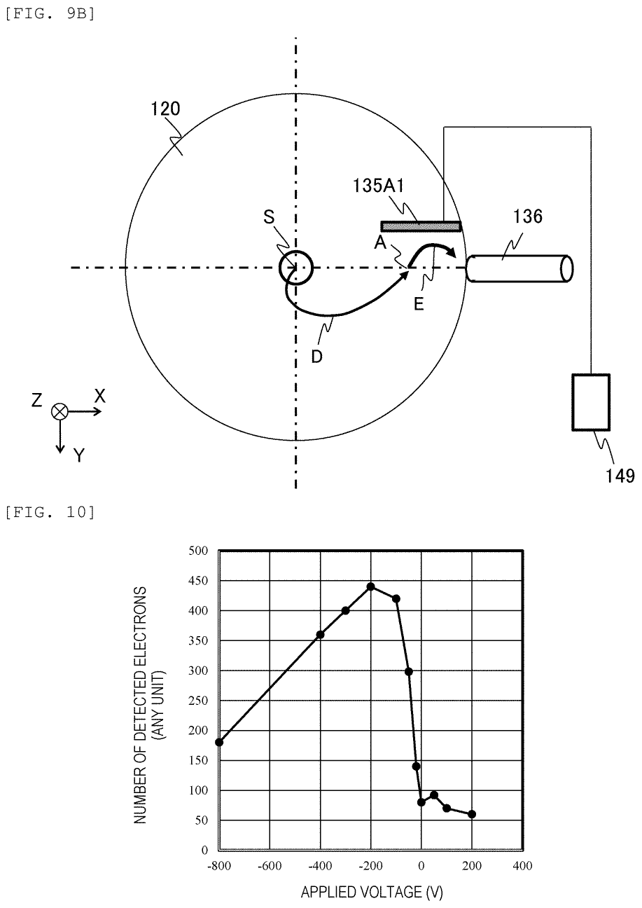

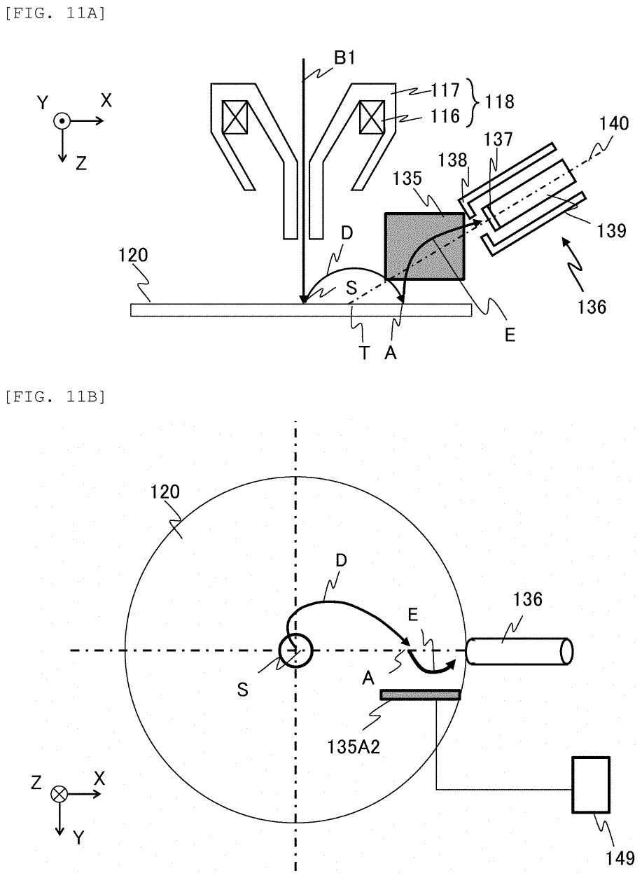

The compensation electrode 135 according to the third embodiment will be described with reference to FIGS. 9A and 9B. FIG. 9A is a side view, and FIG. 9B is a top view seen from the electron gun 101. In addition, FIGS. 9A and 9B show only one trajectory of electrons among the low angle backscattered electrons D emitted from the point S in all directions.

As in the first embodiment, the compensation electrode 135 shown in FIGS. 9A and 9B is provided between the second detector 136 and the point A at which the low angle backscattered electrons D collide with the sample 120. However, the compensation electrode 135 is implemented with the electrode 135A1 which is one of the electrode 135A1 and the electrode 135A2 which are parallel to each other as described in the first embodiment. In addition, as shown in FIG. 9B, the low angle backscattered electrons D are rotated counterclockwise by the leakage magnetic field so as to be directed toward the electrode 135A1, and the third electrons E are emitted from the point A colliding with the sample 120. In FIG. 9B, when a negative voltage is applied to the electrode 135A1, although the third electrons E temporarily approach the electrode 135A1, the trajectory of the third electrons E are controlled so as to be directed to the second detector 136 by an electric field formed around the electrode 135A1. That is, the proportion of the third electrons E detected by the second detector 136 can be controlled by adjusting the intensity of the electric field formed around the electrode 135A1 in the space where the magnetic field leaked from the semi-in-lens, which is the objective lens, exists.

An example of a correlation between the voltage applied to the electrode 135A1 of FIG. 9B and the number of the third electrons E detected by the second detector 136 will be described with reference to FIG. 10. FIG. 10 shows a correlation obtained by electron trajectory analysis as in FIG. 6. A horizontal axis represents the voltage applied to the electrode 135A1, and a vertical axis represents the number of the third electrons E detected by the second detector 136.

FIG. 10 shows that the number of the third electrons E detected when a voltage of −200 V is applied to the electrode 135A1 is the largest, which is about six times the number of the third electrons E detected when no voltages are applied. However, when a positive voltage is applied to the electrode 135A1, there is no large change in the number of the detected third electrons E. That is, similarly to the first embodiment, it is desirable to apply a voltage to the electrode 135A1 such that an electric field is formed in a direction in which the rotation of the low angle backscattered electrons D due to the leakage magnetic field is prevented.

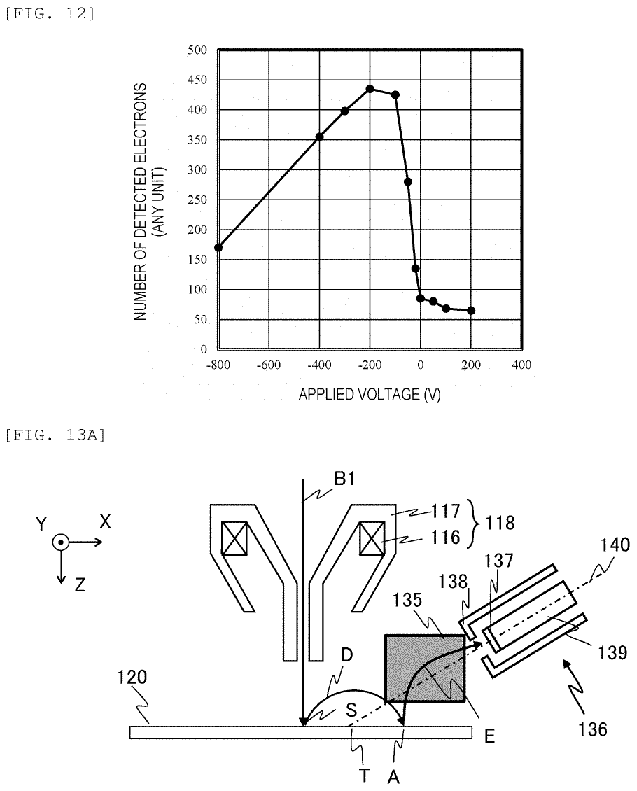

A modification of the compensation electrode 135 according to the third embodiment will be described with reference to FIGS. 11A and 11B. FIG. 11A is a side view, and FIG. 11B is a top view seen from the electron gun 101. In addition, FIGS. 11A and 11B show only one trajectory of electrons among the low angle backscattered electrons D emitted from the point S in all directions.

Similarly to FIGS. 9A and 9B, the compensation electrode 135 shown in FIGS. 11A and 11B is provided between the second detector 136 and the point A at which the low angle backscattered electrons D collide with the sample 120. However, the compensation electrode 135 is implemented with the electrode 135A2 which is an electrode on the side opposite to the case of FIGS. 9A and 9B. In addition, as shown in FIG. 11B, the low angle backscattered electrons D are rotated in a clockwise direction, which is an opposite direction to that in FIG. 9B, by the leakage magnetic field so as to be directed toward the electrode 135A2, and the third electrons E are emitted from the point A colliding with the sample 120. In FIG. 11B, when a negative voltage is applied to the electrode 135A2, although the third electrons E temporarily approach the electrode 135A2, the trajectory of the third electrons E is controlled so as to be directed to the second detector 136 by an electric field formed around the electrode 135A2. That is, the proportion of the third electrons E detected by the second detector 136 can be controlled by adjusting the intensity of the electric field formed around the electrode 135A2 in the space where the magnetic field leaked from the semi-in-lens, which is the objective lens, exists.

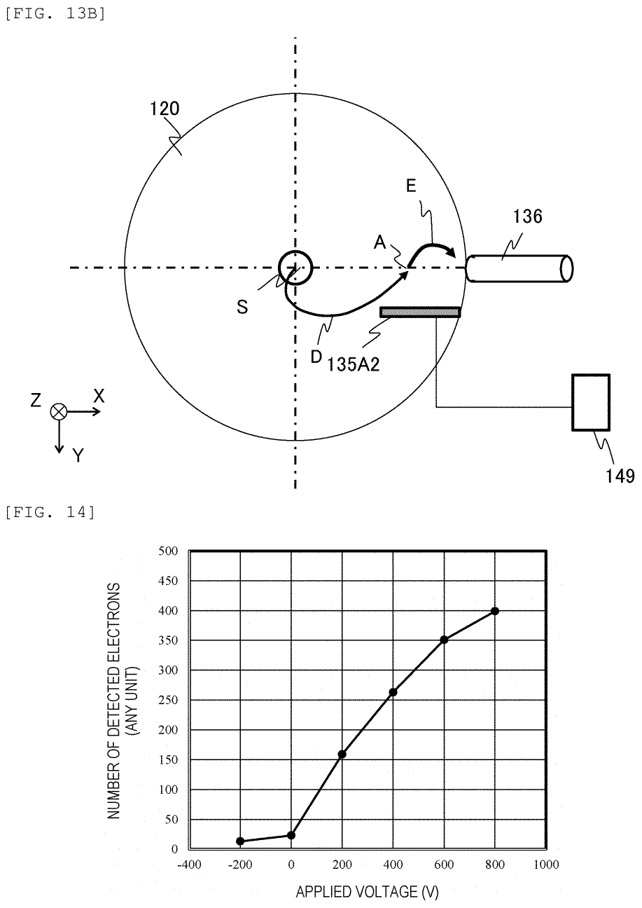

An example of a correlation between the voltage applied to the electrode 135A2 of FIG. 11B and the number of the third electrons E detected by the second detector 136 will be described with reference to FIG. 12. FIG. 12 shows a correlation obtained by electron trajectory analysis as in FIGS. 6 and 10. A horizontal axis represents the voltage applied to the electrode 135A2, and a vertical axis represents the number of the third electrons E detected by the second detector 136.

FIG. 12 shows that the number of the third electrons E detected when a voltage of −200 V is applied to the electrode 135A2 is the largest, and there is no large change in the number of the third electrons E detected when a positive voltage is applied to the electrode 135A2, which is the same tendency as in FIG. 10. That is, similarly to the first embodiment, it is desirable to apply a voltage to the electrode 135A2 such that an electric field is formed in a direction in which the rotation of the low angle backscattered electrons D due to the leakage magnetic field is prevented.

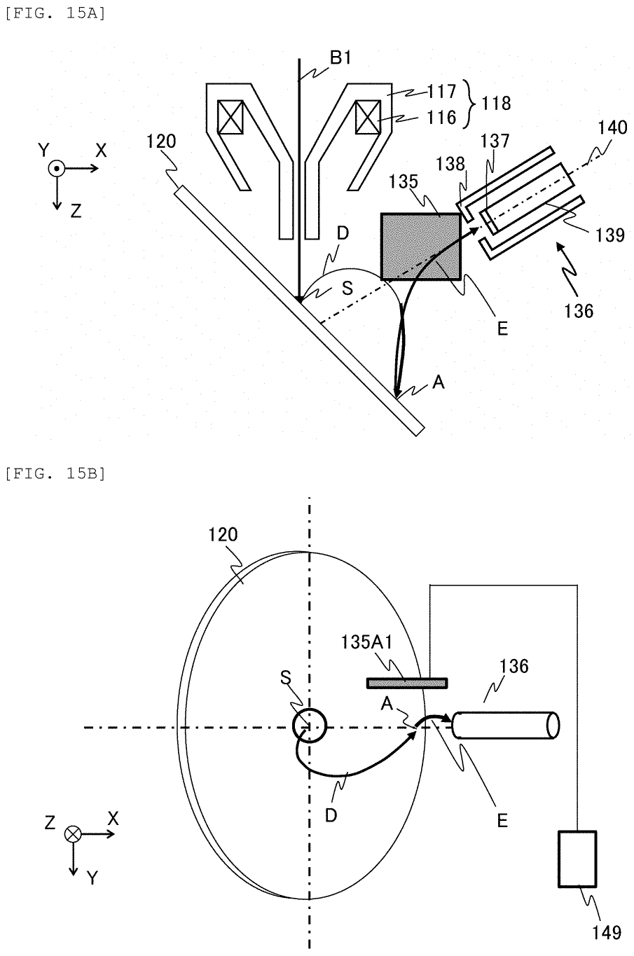

A modification of the compensation electrode 135 according to the third embodiment will be described with reference to FIGS. 13A and 13B. FIG. 13A is a side view, and FIG. 13B is a top view seen from the electron gun 101. In addition, FIGS. 13A and 13B show only one trajectory of electrons among the low angle backscattered electrons D emitted from the point S in all directions.

Similarly to FIGS. 11A and 11B, the compensation electrode 135 shown in FIGS. 13A and 13B is implemented with the electrode 135A2 provided between the second detector 136 and the point A at which the low angle backscattered electrons D collide with the sample 120. In addition, as shown in FIG. 13B, the low angle backscattered electrons D are rotated in a counterclockwise direction, which is an opposite direction to that in FIG. 11B, by the leakage magnetic field so as to move away from the electrode 135A2, and the third electrons E are emitted from the point A colliding with the sample 120. In FIG. 13B, when a positive voltage is applied to the electrode 135A2, although the third electrons E temporarily move away from the electrode 135A2, the trajectory of the third electrons E is controlled so as to be directed to the second detector 136 by an electric field formed around the electrode 135A2. That is, the proportion of the third electrons E detected by the second detector 136 can be controlled by adjusting the intensity of the electric field formed around the electrode 135A2 in the space where the magnetic field leaked from the semi-in-lens, which is the objective lens, exists. In addition, when the compensation electrode 135 is implemented with one of the electrode 135A1 and the electrode 135A2, it is possible to detect the third electrons E by switching a polarity of the voltage applied to the compensation electrode 135 according to the direction of the leakage magnetic field.

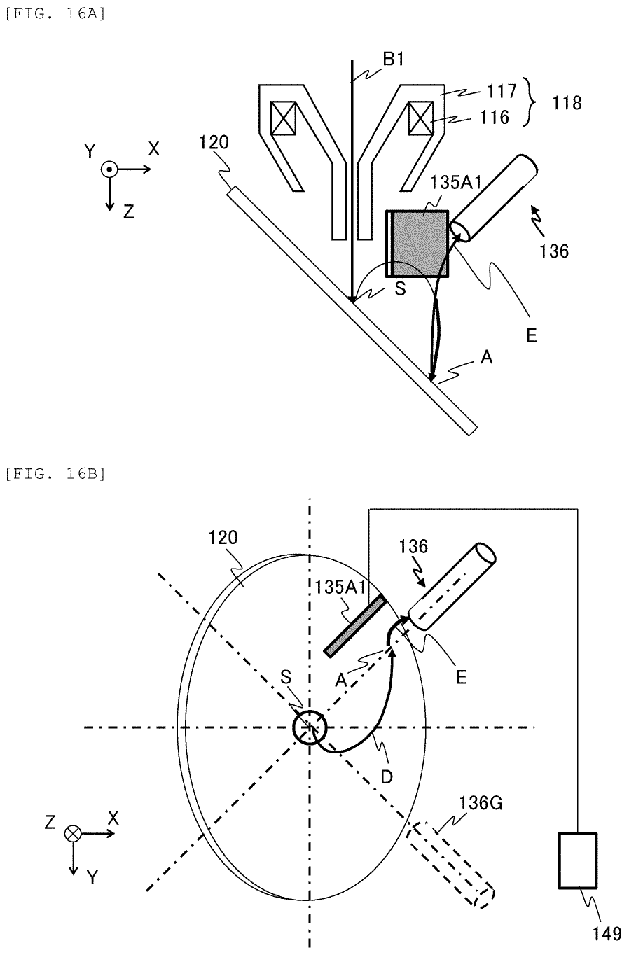

An example of a correlation between the voltage applied to the electrode 135A2 of FIG. 13B and the number of the third electrons E detected by the second detector 136 will be described with reference to FIG. 14. FIG. 14 shows a correlation obtained by electron trajectory analysis as in FIGS. 6, 10, and 12. A horizontal axis represents the voltage applied to the electrode 135A2, and a vertical axis represents the number of the third electrons E detected by the second detector 136.

FIG. 14 shows that the number of the detected third electrons E does not increase so much when a negative voltage is applied to the electrode 135A2, and the number of the detected third electrons E increases as a positive voltage applied to the electrode 135A2 increases. That is, similarly to the first embodiment, it is desirable to apply a voltage to the electrode 135A2 such that an electric field is formed in a direction in which the rotation of the low angle backscattered electrons D due to the leakage magnetic field is prevented.

In addition, in order to make the number of the third electrons E detected in FIG. 14 equal to that in FIG. 12, it is necessary to further increase an absolute value of the voltage applied to the electrode 135A2. That is, since the intensity of the electric field formed by the electrode 135A2 increases as a position is closer to the electrode 135A2, the third electrons E away from the electrode 135A2 require a higher voltage than that of the third electrons E closer to the electrode 135A2.

According to the third embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the compensation electrode 135 according to the third embodiment includes only one of the electrode 135A1 and the electrode 135A2, it is possible to provide an electron microscope having a simple structure and a low manufacturing cost.

### Fourth Embodiment

In the first embodiment, the case where the sample 120 is kept horizontal has been described. In a fourth embodiment, a case where the sample 120 is inclined with respect to the horizontal plane will be described. Since some of the configurations and functions described in the first embodiment can be applied to the fourth embodiment, the same reference numerals are used for the same configurations and functions, and the description thereof will be omitted.

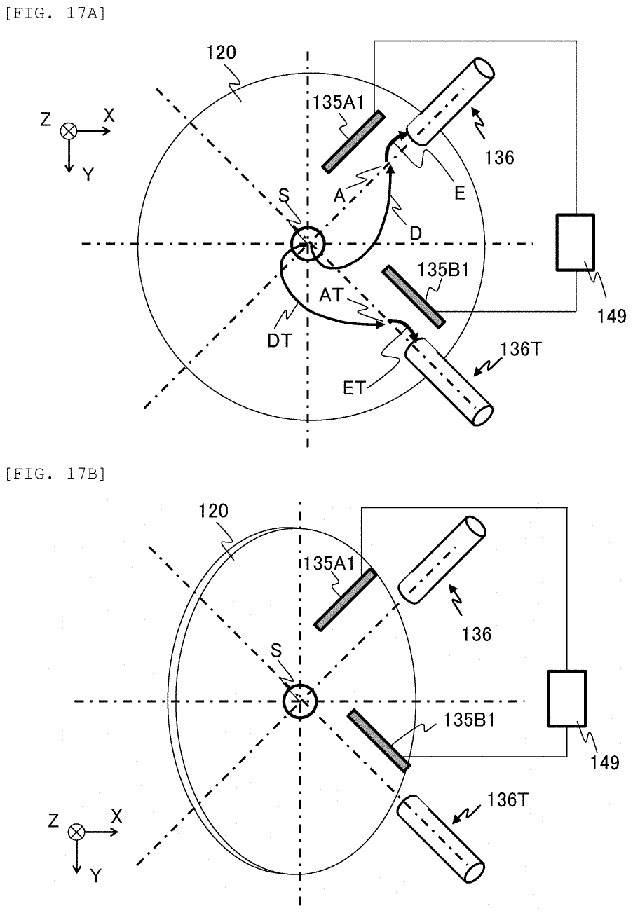

The fourth embodiment will be described with reference to FIGS. 15A and 15B. FIG. 15A is a side view, and FIG. 15B is a top view seen from the electron gun 101. In addition, FIGS. 15A and 15B show only one trajectory of electrons among the low angle backscattered electrons D emitted from the point S in all directions.

Similarly to FIGS. 9A and 9B, the compensation electrode 135 shown in FIGS. 15A and 15B is implemented with the electrode 135A1, and is provided between the second detector 136 and the point A at which the low angle backscattered electrons D collide with the sample 120. In addition, when the sample stage 121 is inclined by 45° with respect to the horizontal plane, the sample 120 held by the sample stage 121 is also inclined by 45° with respect to the horizontal plane. In FIG. 15B, since the point A at which the low angle backscattered electrons D collide with the sample 120 is further away from the objective lens 118, the magnetic field intensity in the vicinity of the point A is weak, and the third electrons E emitted from the point A easily reach the second detector 136. In order to avoid collision with the sample 120, the electrode 135A1 and the second detector 136 are provided on the side where the sample 120 is lowered.

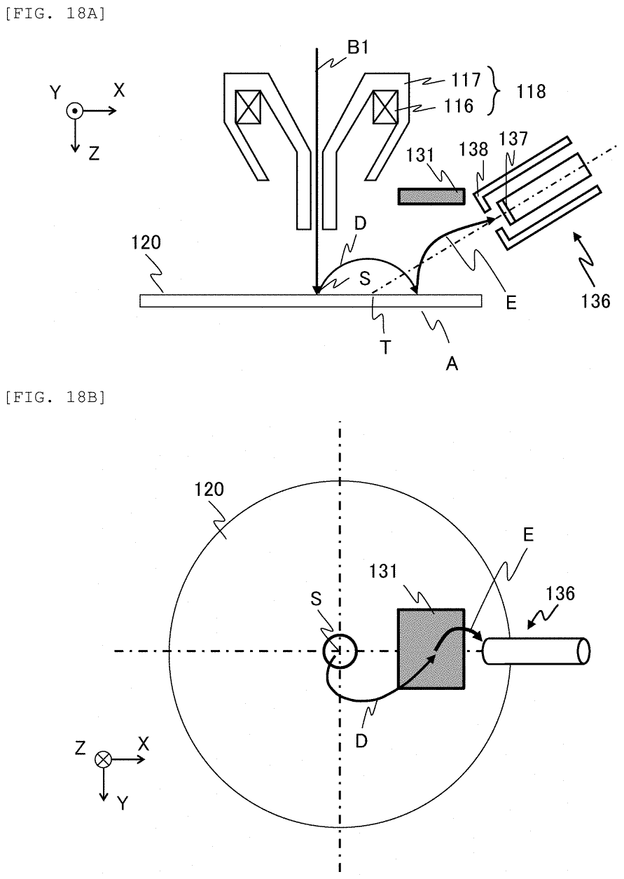

A modification of the fourth embodiment will be described with reference to FIGS. 16A and 16B. FIG. 16A is a side view, and FIG. 16B is a top view seen from the electron gun 101. In addition, FIGS. 16A and 16B show only one trajectory of electrons among the low angle backscattered electrons D emitted from the point S in all directions.

Similarly to FIGS. 9A and 9B, the compensation electrode 135 and the second detector 136 shown in FIGS. 16A and 16B are implemented with the electrode 135A1, and are provided between the second detector 136 and the point A at which the low angle backscattered electrons D collide with the sample 120. In addition, similarly to FIGS. 15A and 15B, the sample 120 is inclined by 45° with respect to the horizontal plane. However, in order to improve a detection rate of the third electrons E, the sample 120 is inclined such that the electrode 135A1 and the second detector 136 are inclined with respect to an inclination direction of the sample 120 and disposed on a side toward which the low angle backscattered electrons D are directed as shown in FIG. 16B. On the other hand, at a position of a second detector 136G indicated by a dotted line, the detection rate of the third electrons E decreases. When a direction of the leakage magnetic field is reversed, the detection rate of the third electrons E is improved at the position of the second detector 136G. That is, a direction in which the sample 120 is inclined may be set according to the direction of the leakage magnetic field and the position of the second detector 136 so as to improve the detection rate of the third electrons E in the second detector 136. In addition, the direction of the leakage magnetic field may be set such that the detection rate of the third electrons E in the second detector 136 is improved.

According to the fourth embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the third electrons E can be detected even when the sample 120 is inclined with respect to the horizontal plane, a backscattered electron image having a high SNR can be obtained.

### Fifth Embodiment

In the first to fourth embodiments, the case where a set of the compensation electrode 135 and the second detector 136 is provided has been described. In a fifth embodiment, a case where two sets of the compensation electrode 135 and the second detector 136 are provided will be described. Since some of the configurations and functions described in the first embodiment can be applied to the fifth embodiment, the same reference numerals are used for the same configurations and functions, and the description thereof will be omitted.

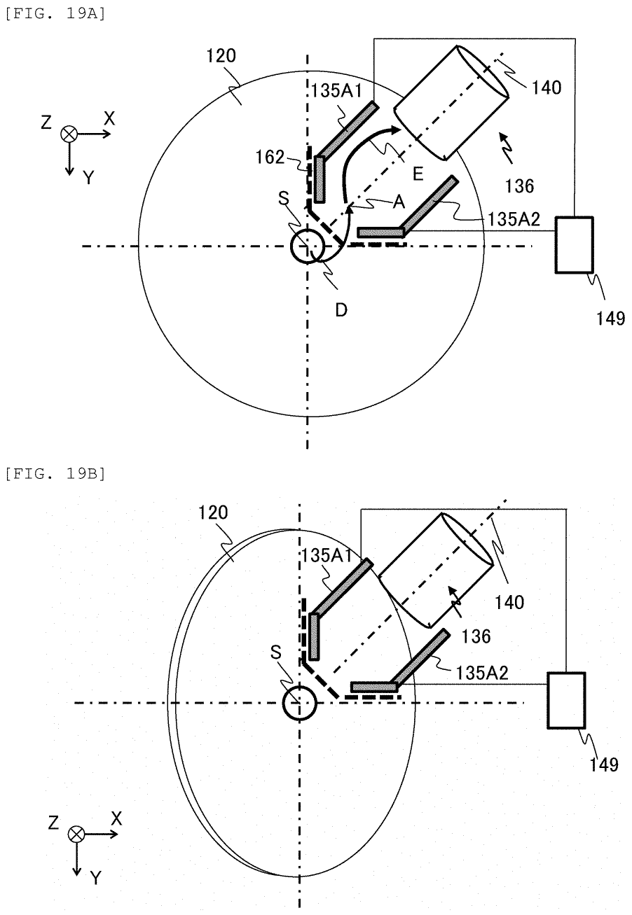

The fifth embodiment will be described with reference to FIGS. 17A and 17B. FIGS. 17A and 17B are top views seen from the electron gun 101. In FIG. 17A, the sample 120 is kept horizontal, and in FIG. 17B, the sample 120 is inclined in the same manner as in FIG. 16B. In addition, FIG. 17A shows two trajectories of electrons among the low angle backscattered electrons D emitted from the point S in all directions.

In FIGS. 17A and 17B, a set of the electrode 135A1 and the second detector 136 is provided in the same manner as in FIG. 16B, and a set of an electrode 135B1 and a second detector 136T is provided. An angle formed by respective half straight lines extending from the point S to the second detector 136 and the second detector 136T is 90°.

The electrode 135A1 is provided between the second detector 136 and the point A at which the low angle backscattered electrons D collide with the sample 120, and superimposes an electric field such that the third electrons E emitted from the point A are directed to the second detector 136 in a space where a magnetic field leaked from the objective lens 118 exists. In addition, the electrode 135B1 is provided between the second detector 136T and a point AT at which a low angle backscattered electrons DT collide with the sample 120, and superimposes an electric field such that third electrons ET emitted from the point AT are directed to the second detector 136T in a space where a magnetic field leaked from the objective lens 118 exists.

Since the third electrons E detected by the second detector 136 and the third electrons ET detected by the second detector 136T are emitted by collision of the low angle backscattered electrons D and the low angle backscattered electrons DT, which have different azimuth angles, with the sample 120, two backscattered electron images having different azimuth angles can be obtained. Since the obtained two backscattered electron images are shadow images whose illumination directions are different from each other by 90°, an uneven structure of the sample 120 can be more clearly grasped by observation of the two backscattered electron images. When the two sets of the compensation electrode 135 and the second detector 136 are disposed as shown in FIG. 17B, two backscattered electron images having different azimuth angles can be obtained even when the sample 120 is inclined.

According to the fifth embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since two backscattered electron images having different azimuth angles can be obtained, the uneven structure of the sample 120 can be more clearly grasped.

### Sixth Embodiment

In the first to fifth embodiments, the case where the compensation electrode 135 is provided between the second detector 136 and the point A at which the low angle backscattered electrons D collide with the sample 120 has been described. In a sixth embodiment, a case where a compensation magnetic pole that forms a magnetic field for controlling the trajectory of the third electrons E is provided instead of the compensation electrode 135 will be described. Since some of the configurations and functions described in the first embodiment can be applied to the sixth embodiment, the same reference numerals are used for the same configurations and functions, and the description thereof will be omitted.

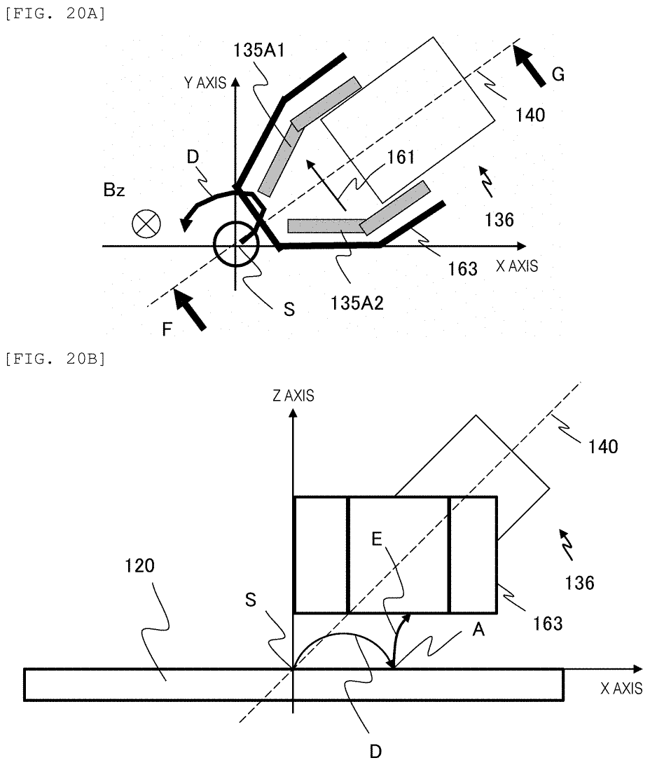

The sixth embodiment will be described with reference to FIGS. 18A and 18B. FIG. 18A is a side view, and FIG. 18B is a top view seen from the electron gun 101. In addition, FIGS. 18A and 18B show only one trajectory of electrons among the low angle backscattered electrons D emitted from the point S in all directions.

FIGS. 18A and 18B show a compensation magnetic pole 131 provided between the second detector 136 and the point A at which the low angle backscattered electrons D collide with the sample 120. The compensation magnetic pole 131 forms a magnetic field that acts to prevent the rotation of the low angle backscattered electrons D due to the leakage magnetic field. That is, a magnetic field in a direction opposite to a direction of the leakage magnetic field is formed by the compensation magnetic pole 131. The magnetic field formed by the compensation magnetic pole 131 acts such that the third electrons E emitted from the point A at which the low angle backscattered electrons D collide with the sample 120 are directed to the second detector 136. As a result, the number of the third electrons E detected by the second detector 136 increases, and a backscattered electron image having a high SNR can be obtained.

When a current flowing through the objective lens coil 117 is reversed, the direction of the magnetic field formed by the compensation magnetic pole 131 may be controlled to be reversed. Further, it is desirable that the compensation magnetic pole 131 is disposed sufficiently away from a region where the low angle backscattered electrons D fly. In addition, instead of the compensation magnetic pole 131, a magnetic shielding material that shields the leakage magnetic field may be provided between the point A and the second detector 136.

According to the sixth embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, when a permanent magnet is used as the compensation magnetic pole 131, it is not necessary to provide a power supply used for the compensation magnetic pole 131, and thus it is possible to provide an electron microscope having a simple structure and low manufacturing cost and running cost.

### Seventh Embodiment

In the first to fifth embodiments, a case where a flat electrode is provided as the compensation electrode 135 has been described. In a seventh embodiment, a case where an electrode having a bent shape is provided as the compensation electrode 135 will be described. Since some of the configurations and functions described in the first embodiment can be applied to the seventh embodiment, the same reference numerals are used for the same configurations and functions, and the description thereof will be omitted.

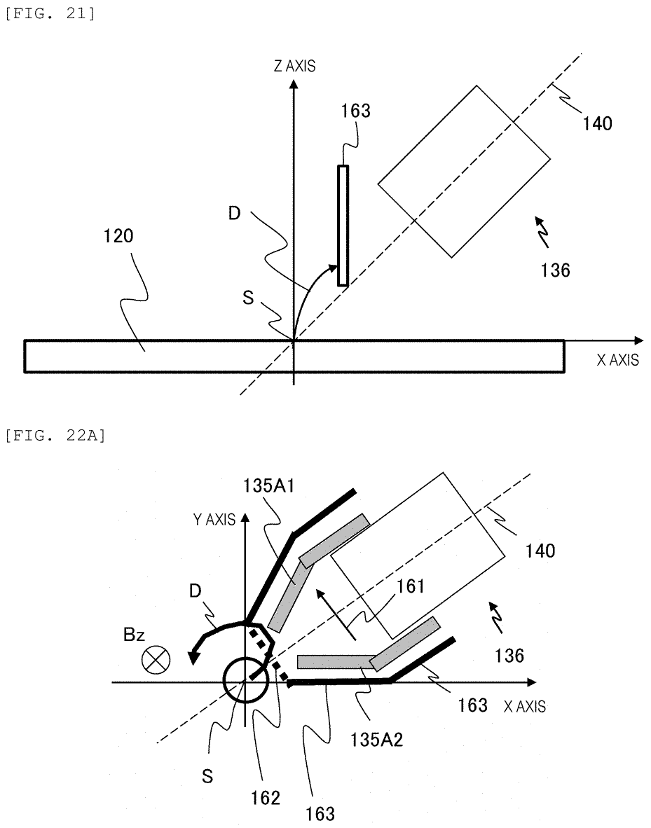

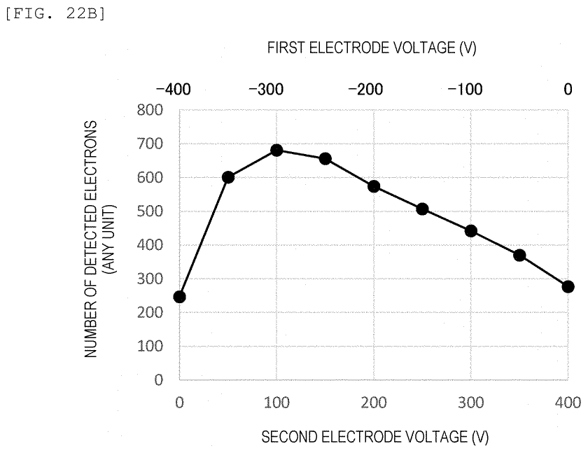

The seventh embodiment will be described with reference to FIGS. 19A and 19B. FIGS. 19A and 19B are top views seen from the electron gun 101. In FIG. 19A, the sample 120 is kept horizontal, and in FIG. 19B, the sample 120 is inclined by 45°. An inclined axis is an axis parallel to a Y axis. In addition, FIG. 19A shows one trajectory of electrons among the low angle backscattered electrons D emitted from the point S in all directions.

The electrode 135A1 and the electrode 135A2 are provided between the second detector 136 and the point A at which the low angle backscattered electrons D collide with the sample 120. In a space where a magnetic field leaked from the objective lens 118 exists, an electric field is superimposed such that the third electrons E emitted from the point A are directed to the second detector 136. Accordingly, a backscattered electron image in which an azimuth angle of backscattered electron emission is limited is obtained.

Here, in the present embodiment, as shown in FIGS. 19A and 19B, the electrode 135A1 and the electrode 135A2 are bent by 45° toward the electrodes facing each other on the side closer to the S point irradiated with the primary electron beam B1, that is, on the side closer to the objective lens. It is found that a probability of the third electrons E reaching the second detector 136 in this manner is particularly high. In particular, an effect is high when excitation of the objective lens is strong and a position A where backscattered electrons collide is close to the point S. Accordingly, a backscattered electron image having a high SNR is obtained. That is, the uneven structure of the sample 120 can be more clearly grasped. It is important that the electrode 135A1 is bent inward as shown in FIG. 19A. As a result, a distance between the electrode 135A1 and the facing electrode 135A2 is shorter on the front end side than on the side closer to the detector. In addition, it can be expressed that the electrode 135A1 is bent toward the center line 140 of the second detector 136 on the side closer to the objective lens side. That is, when the electrode 135A1 is bent toward the center line 140 of the detector as shown in FIG. 19B, even when a stage is inclined with an axis parallel to the Y axis as shown in FIG. 19B, the electrode 135A1 and the stage do not interfere with each other.

In FIG. 19A, the electrode 135A2 is also bent toward the center line of the detector on the side closer to the objective lens. It is found that a probability of the third electrons E reaching the second detector 136 in this manner is particularly high. However, an effect of the electrode 135A1 is larger in the magnetic field condition of the objective lens of the seventh embodiment. That is, in the seventh embodiment, both the electrode 135A1 and the electrode 135A2 are bent, but one of the electrode 135A1 and the electrode 135A2 may be bent alone. In addition, the flat plate is bent in FIG. 19A, but may also be bent in an arc shape, and is not always necessary to be a flat plate.

The direction of bend of the compensation electrode toward the center line 140 of the second detector 136 is not limited to one direction. When the space in the vicinity of the second detector 136 is roughly divided into a space including the center line 140 of the second detector 136 and a space not including the center line 140, the compensation electrode may be bent or curved toward the space in which the center line 140 of the second detector 136 is included. A position and direction of the start of the bend and the curve, an angle of the bend, and a curvature of the curve are not limited.

In addition, it is found that the same effect can be obtained when a distance between the two compensation electrodes is smaller on the side closer to the electron side than on the side closer to the objective lens side and the side closer to the detector. That is, the same effect can be obtained if there is a portion where a distance between the compensation electrode and the center line of the detector is shorter on the side closer to the objective lens than on the side closer to the detector.

In addition, in FIGS. 19A and 19B, the grid electrode 162 is inserted between the compensation electrode 135 and the point S as described in the second embodiment. In this case, an effect is obtained in which an influence of a compensation electrode voltage on an electron beam can be reduced.

According to the seventh embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since it is possible to detect the third electrons particularly with high efficiency, it is possible to obtain a backscattered electron image having a high SNR, and thus it is possible to more clearly grasp the uneven structure of the sample 120.

### Eighth Embodiment

In the second embodiment, the case where the grid electrode 162 is provided together with the compensation electrode 135 including the electrode 135A1 and the electrode 135A2 has been described. In an eighth embodiment, at least a part of the grid electrode 162 is implemented with a plate material. Since some of the configurations and functions described in the first embodiment can be applied to the eighth embodiment, the same reference numerals are used for the same configurations and functions, and the description thereof will be omitted.

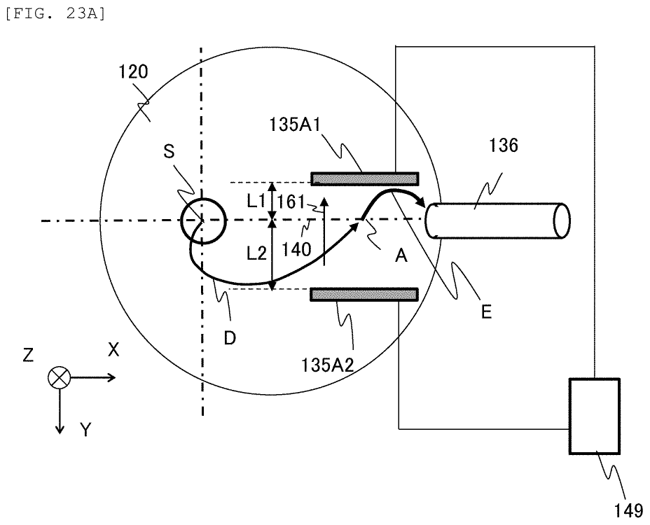

The compensation electrode 135 according to the eighth embodiment and a plate electrode 163, which is an electrode implemented with a plate material, will be described with reference to FIGS. 20A and 20B. FIG. 20A is a top view seen from the electron gun 101, and FIG. 20B is a side view. The second detector 136 is disposed such that the center line 140 has an inclination of 30° with respect to an X axis which is an inclination direction of the sample 120.

As in the seventh embodiment, the compensation electrode 135 includes the electrode 135A1 and the electrode 135A2 that are disposed substantially perpendicular to the surface of the sample 120 and have shapes bent toward the center line 140 of the second detector 136. A negative voltage is applied to the electrode 135A1, and a positive voltage is applied to the electrode 135A2, such that an electric field in the direction of the arrow 161 is formed between the electrode 135A1 and the electrode 135A2. The electric field in the direction of the arrow 161 acts in the space between the electrode 135A1 and the electrode 135A2 to prevent the counterclockwise rotation of the low angle backscattered electrons D as shown in FIG. 20A and to direct the third electrons E emitted by the collision of the low angle backscattered electrons D with the point A toward the second detector 136.

Here, in the space between the electrode 135A1 and the electrode 135A2, when the rotation direction of the low angle backscattered electrons D can be decomposed with at least the direction of the electric field as one component, it is assumed that the rotation direction of the low angle backscattered electrons D and the electric field are the same direction. The rotation direction of the low angle backscattered electrons D need not be completely the same as the direction of the electric field. In addition, when the rotation direction of the low angle backscattered electrons D can be decomposed with the direction opposite to the direction of the electric field as one component, the rotation direction of the low angle backscattered electrons D and the electric field are opposite to each other. The rotation direction of the low angle backscattered electrons D need not be completely opposite to the direction of the electric field. That is, the rotation direction of the low angle backscattered electrons D shown in FIG. 20A is the same direction as the electric field of the arrow 161.

The plate electrode 163 is disposed substantially perpendicular to the surface of the sample 120 and between the primary electron beam B1 and the compensation electrode 135, and has a shape covering the compensation electrode 135 along the compensation electrode 135. The plate electrode 163 has the same potential as that of the outside of the objective lens 118. In addition, the plate electrode 163 is not disposed between the point A from which the third electrons E are emitted and the second detector 136.

Since the plate electrode 163 is disposed between the primary electron beam B1 and the compensation electrode 135, an adverse effect of an electric field formed by the compensation electrode 135 on the primary electron beam B1 is reduced. That is, the plate electrode 163 functions as a shield electrode that shields the electric field formed by the compensation electrode 135, prevents deflection of the primary electron beam B1 and distortion of a beam shape, and prevents degradation of the image resolution of the electron microscope. The grid electrode 162 according to the second embodiment also functions as a shield electrode because the grid electrode 162 substantially shields the electric field formed by the compensation electrode 135.

When the plate electrode 163 is used as the shield electrode, the low angle backscattered electrons D having a relatively large emission angle, which is an angle formed by the trajectory of the low angle backscattered electrons D emitted from the point S and the surface of the sample 120, collide with the plate electrode 163 as shown in FIG. 21. As a result, since only the third electrons E, which are emitted by the collision of the low angle backscattered electrons D having a relatively small emission angle with the point A, are detected by the second detector 136, a backscattered electron image in which the unevenness of the sample is clearer is formed. Further, when the plate electrode 163 is used as the shield electrode, a structure of the shield electrode is simplified, and the manufacturing cost can be reduced.

When the grid electrode 162 is used as the shield electrode, a part of the low angle backscattered electrons D having a relatively large emission angle passes through the grid electrode 162 and collides with the sample 120, and therefore, the number of the third electrons E detected by the second detector 136 increases and a brighter backscattered electron image is formed.

According to the eighth embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since an increase in the beam diameter of the primary electron beam B1 can be prevented and the detection efficiency of the second detector 136 can be improved by the shield electrode such as the plate electrode 163, an image quality of the backscattered electron image can be improved. In particular, when the plate electrode 163 is used as the shield electrode, a backscattered electron image in which the unevenness of the sample is clearer is formed, and the manufacturing cost can be reduced.

### Ninth Embodiment

In the first embodiment, the case where voltages having opposite polarities and equal absolute values are applied to the electrode 135A1 and the electrode 135A2 forming the compensation electrode 135 has been described. In a ninth embodiment, a case where voltages having opposite polarities and different absolute values are applied to the electrode 135A1 and the electrode 135A2 will be described. Since some of the configurations and functions described in the first embodiment can be applied to the ninth embodiment, the same reference numerals are used for the same configurations and functions, and the description thereof will be omitted.

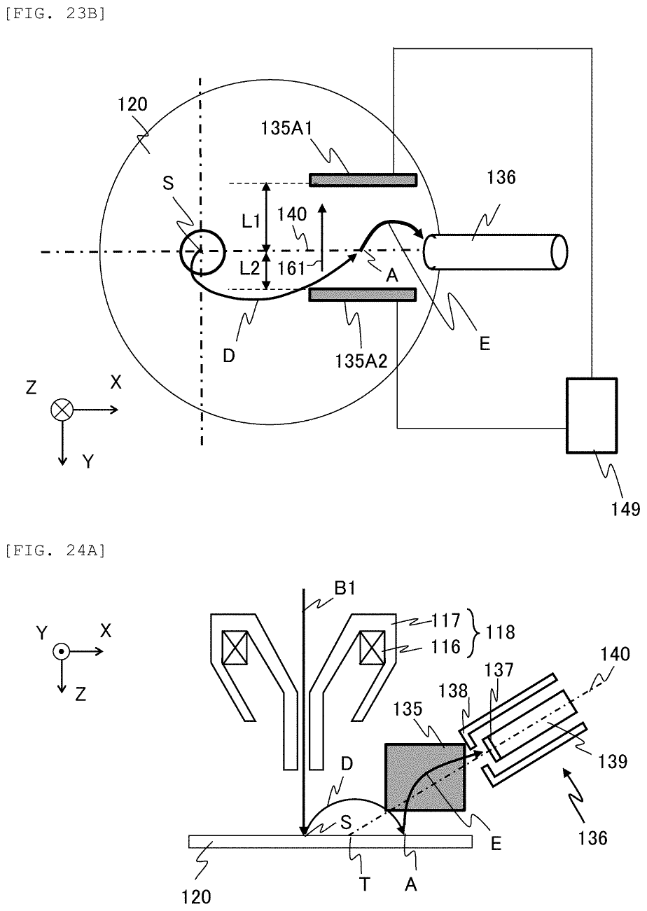

The ninth embodiment will be described with reference to FIGS. 22A and 22B. FIG. 22A is a top view seen from the electron gun 101, and FIG. 22B shows an example of a result of obtaining, by electron trajectory analysis, a correlation between the voltages applied to the electrode 135A1 and the electrode 135A2 and the number of the third electrons E detected by the second detector 136. The second detector 136 is disposed such that the center line 140 has an inclination of 30° with respect to the X axis which is the inclination direction of the sample 120.

As in the seventh embodiment, the compensation electrode 135 includes the electrode 135A1 and the electrode 135A2 that are disposed substantially perpendicular to the surface of the sample 120 and have shapes bent toward the center line 140 of the second detector 136. The electrode 135A1 and the electrode 135A2 are disposed at the same distance from the center line 140. In addition, a negative voltage is applied to the electrode 135A1, and a positive voltage is applied to the electrode 135A2, such that an electric field in the direction of the arrow 161 is formed between the electrode 135A1 and the electrode 135A2.

A combination of the grid electrode 162 and the plate electrode 163 is used as a shield electrode. That is, the grid electrode 162 is disposed on a plane orthogonal to the center line 140 of the second detector 136, and the plate electrode 163 having a shape along the compensation electrode 135 is arranged continuous with the grid electrode 162. By using such a shield electrode, since a part of the low angle backscattered electrons D having a relatively large emission angle passes through the grid electrode 162 and collides with the sample 120, the number of the third electrons E detected by the second detector 136 increases, and a brighter backscattered electron image is formed. In addition, since the plate electrode 163 is disposed along the compensation electrode 135, an adverse effect of an electric field formed by the compensation electrode 135 on the primary electron beam B1 is reduced. That is, since deflection of the primary electron beam B1 and distortion of a beam shape are prevented, degradation of the image resolution of the electron microscope can be prevented.

FIG. 22B shows the correlation between the voltages applied to the electrode 135A1 and the electrode 135A2 and the number of the third electrons E detected by the second detector 136 in the configuration of FIG. 22A. In FIG. 22B, the vertical axis represents the number of the third electrons E detected by the second detector 136, and the horizontal axis represents a first electrode voltage, which is the voltage applied to the electrode 135A1, and a second electrode voltage, which is the voltage applied to the electrode 135A2. A difference between the first electrode voltage and the second electrode voltage is fixed to 400 V, and an intensity of an electric field formed by the compensation electrode 135 is kept constant, such that an adverse effect on the primary electron beam B1 is not increased. In addition, since the first electrode voltage is a negative voltage and the second electrode voltage is a positive voltage, an electric field in the direction of the arrow 161 is formed between the electrode 135A1 and the electrode 135A2, and the direction of the electric field is the same as the rotation direction of the low angle backscattered electrons D.

FIG. 22B shows that the number of detected electrons is larger when the first electrode voltage is set to −300 V and the second electrode voltage is set to 100 V than when the first electrode voltage is set to −200 V and the second electrode voltage is set to 200 V, that is, when absolute values of both voltages are equal. This result is based on that the trajectory of the third electrons E is inclined with respect to the center line 140 of the second detector 136. That is, the third electrons E have a trajectory that moves away from the electrode 135A2 applied with the positive voltage and approaches the electrode 135A1 applied with the negative voltage, and is less likely to be affected by the positive voltage and is likely to be affected by the negative voltage. Therefore, the number of detected electrons of the third electrons E can be increased by applying voltages having opposite polarities and different absolute values, instead of applying voltages having equal absolute values, to the electrode 135A1 and the electrode 135A2 disposed at the same distance from the center line 140 of the second detector 136.

According to the ninth embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the number of detected electrons of the third electrons E is increased by applying voltages having opposite polarities and different absolute values to the electrode 135A1 and the electrode 135A2 disposed at the same distance from the center line 140 of the second detector 136, a brighter backscattered electron image can be obtained.

In addition, by using a shield electrode in which the grid electrode 162 and the plate electrode 163 are combined, it is possible to reduce an adverse effect of the electric field formed by the compensation electrode 135 on the primary electron beam B1 and to increase the number of detected electrons of the third electrons E. As a result, it is possible to obtain a brighter electron microscope image having a high resolution.

### 10th Embodiment

In the first embodiment, the electrode 135A1 and the electrode 135A2 forming the compensation electrode 135 are disposed at the same distance from the center line 140 of the second detector 136, that is, disposed symmetrically with respect to the center line 140. In a 10th embodiment, a case where the electrode 135A1 and the electrode 135A2 are disposed at different distances from the center line 140, that is, a case where the electrode 135A1 and the electrode 135A2 are disposed asymmetrically with respect to the center line 140 will be described. Since some of the configurations and functions described in the first embodiment can be applied to the 10th embodiment, the same reference numerals are used for the same configurations and functions, and the description thereof will be omitted.

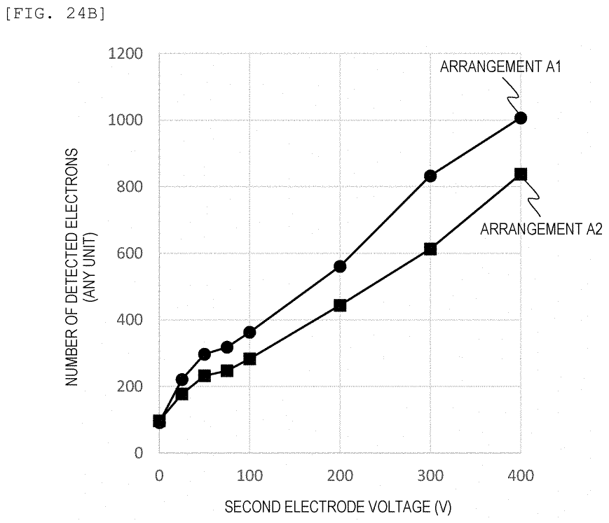

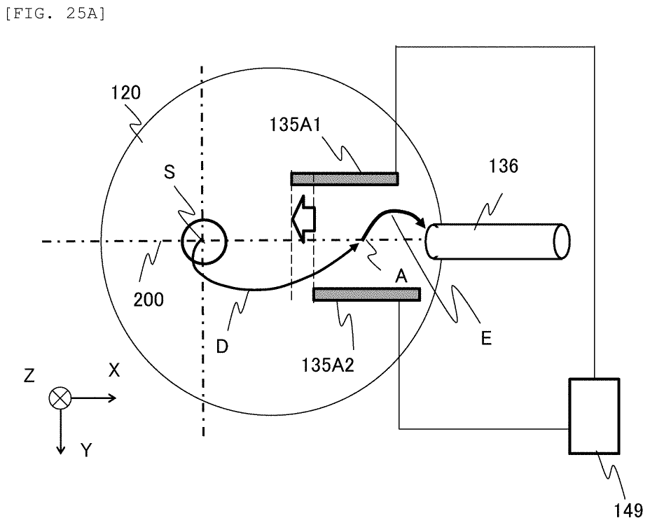

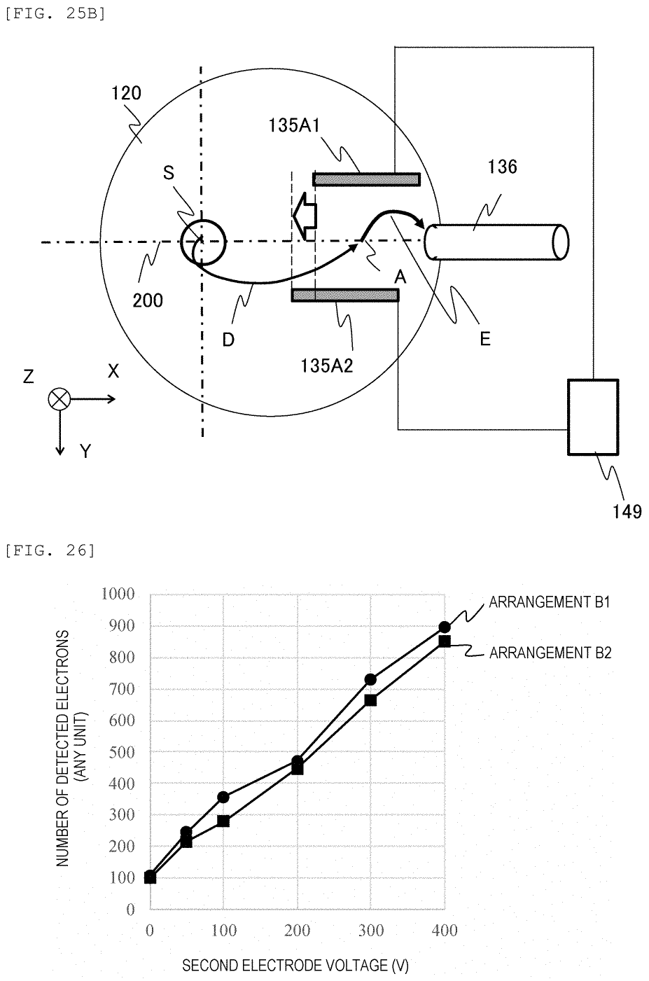

The 10th embodiment will be described with reference to FIGS. 23A, 23B, 24A, and 24B. FIGS. 23A and 23B are top views seen from the electron gun 101. In addition, FIG. 24A is a side view, and FIG. 24B shows an example of a result of obtaining, by electron trajectory analysis, a correlation between the voltage applied to the compensation electrode 135 and the number of the third electrons E detected by the second detector 136. In addition, FIGS. 23A, 23B, and 24A show only one trajectory of electrons among the low angle backscattered electrons D emitted from the point S in all directions, and show a trajectory in which the third electrons E emitted by the collision of the low angle backscattered electrons D with the point A are incident on the second detector 136.

As in the first embodiment, the compensation electrode 135 includes the electrode 135A1 and the electrode 135A2, which are flat plates parallel to each other, and is disposed substantially perpendicular to the surface of the sample 120. In addition, a negative voltage is applied to the electrode 135A1, and a positive voltage is applied to the electrode 135A2, such that an electric field in the direction of the arrow 161 is formed between the electrode 135A1 and the electrode 135A2. Absolute values of the voltages applied to the electrode 135A1 and the electrode 135A2 are equal to each other.

L1<L2 is satisfied in FIG. 23A and L1>L2 is satisfied in FIG. 23B, where L1 is a distance from the electrode 135A1 to the center line 140 and L2 is a distance from the electrode 135A2 to the center line 140. In addition, a distance from the electrode 135A1 to the primary electron beam B1 or the second detector 136 is shorter when L1<L2. Here, an arrangement satisfying L1<L2 as shown in FIG. 23A is referred to as an arrangement A1, and an arrangement satisfying L1>L2 as shown in FIG. 23B is referred to as an arrangement A2.

FIG. 24B shows that the number of detected electrons of the third electrons E is larger in the arrangement A1 than in the arrangement A2. As described in the ninth embodiment, the third electrons E have a trajectory approaching the electrode 135A1 applied with the negative voltage, and is likely to be affected by the negative voltage. Therefore, the number of detected electrons of the third electrons E can be increased by bringing the electrode 135A1, applied with the negative voltage, closer to the center line 140.

According to the 10th embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the number of detected electrons of the third electrons E is increased by bringing the electrode 135A1, applied with the negative voltage, closer to the center line 140, a brighter backscattered electron image can be obtained.

### 11th Embodiment

In the 10th embodiment, the case where the electrode 135A1 and the electrode 135A2 forming the compensation electrode 135 are disposed at different distances from the center line 140 of the second detector 136, that is, the case where the electrode 135A1 and the electrode 135A2 are disposed asymmetrically has been described. The asymmetric arrangement of the electrode 135A1 and the electrode 135A2 is not limited to the 10th embodiment. In an 11th embodiment, as another example of the asymmetric arrangement of the electrode 135A1 and the electrode 135A2, a case where the electrode 135A1 and the electrode 135A2 are disposed at different distances from the primary electron beam B1 will be described. Since some of the configurations and functions described in the first embodiment can be applied to the 11th embodiment, the same reference numerals are used for the same configurations and functions, and the description thereof will be omitted.

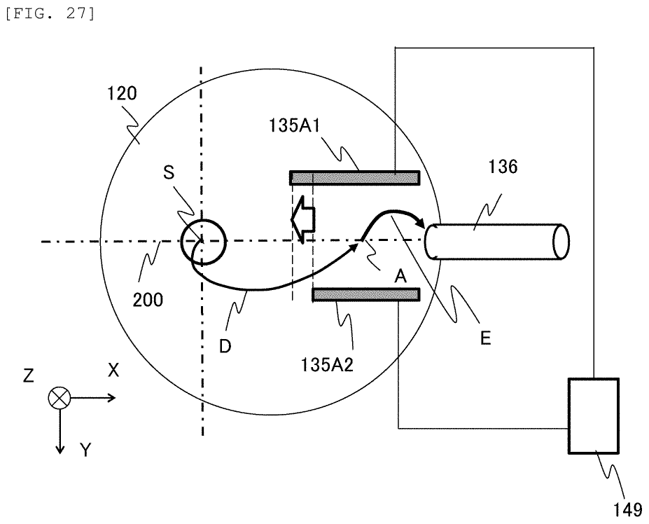

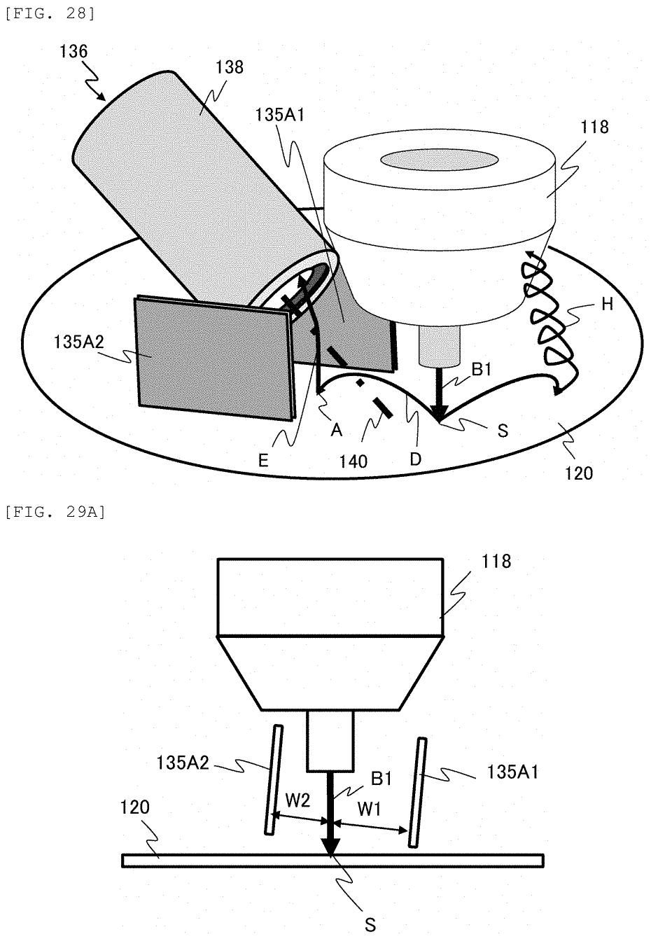

The 11th embodiment will be described with reference to FIGS. 25A, 25B, 26, and 27. FIGS. 25A, 25B, and 27 are top views seen from the electron gun 101, and FIG. 26 shows an example of a result of obtaining, by electron trajectory analysis, a correlation between the voltage applied to the compensation electrode 135 and the number of the third electrons E detected by the second detector 136. In addition, FIGS. 25A and 25B show only one trajectory of electrons among the low angle backscattered electrons D emitted from the point S in all directions, and show a trajectory in which the third electrons E emitted by the collision of the low angle backscattered electrons D with the point A are incident on the second detector 136.

As in the first embodiment, the compensation electrode 135 includes the electrode 135A1 and the electrode 135A2, which are flat plates parallel to each other, and is disposed substantially perpendicular to the surface of the sample 120. In addition, a negative voltage is applied to the electrode 135A1, a positive voltage is applied to the electrode 135A2, and absolute values of the two voltages are equal to each other. In FIG. 25A, a distance between the electrode 135A1 and the primary electron beam B1 or the point S is shorter than a distance between the electrode 135A2 and the primary electron beam B1 or the point S. In FIG. 25B, the distance between the electrode 135A2 and the primary electron beam B1 or the point S is shorter than the distance between the electrode 135A1 and the primary electron beam B1 or the point S. Here, an arrangement in FIG. 25A is referred to as an arrangement B1, and an arrangement in FIG. 23B is referred to as an arrangement B2.

FIG. 26 shows that the number of detected electrons of the third electrons E is larger in the arrangement B1 than in the arrangement B2. As described in the ninth embodiment, the third electrons E have a trajectory approaching the electrode 135A1 applied with the negative voltage, and is likely to be affected by the negative voltage. Therefore, the number of detected electrons of the third electrons E can be increased by bringing the electrode 135A1, applied with the negative voltage, closer to the point S at which the low angle backscattered electrons D are emitted.

The electrode 135A1 and the electrode 135A2 may not necessarily have the same size. As shown in FIG. 27, even when the electrode 135A1 close to the point S is longer in the X direction than the electrode 135A2, the number of detected electrons of the third electrons E can be increased as in the arrangement of FIG. 25A.

According to the 11th embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the number of detected electrons of the third electrons E is increased by bringing the electrode 135A1, applied with the negative voltage, closer to the point S at which the low angle backscattered electrons D are emitted, a brighter backscattered electron image can be obtained.

### 12th Embodiment

In the tenth and 11th embodiments, the case where the electrode 135A1 and the electrode 135A2 forming the compensation electrode 135 are arranged asymmetrically has been described. In a 12th embodiment, as another example of the asymmetric arrangement of the electrode 135A1 and the electrode 135A2, a case where the electrode 135A1 and the electrode 135A2 are inclined with respect to a line perpendicular to the surface of the sample 120 will be described. Since some of the configurations and functions described in the first embodiment can be applied to the 12th embodiment, the same reference numerals are used for the same configurations and functions, and the description thereof will be omitted.

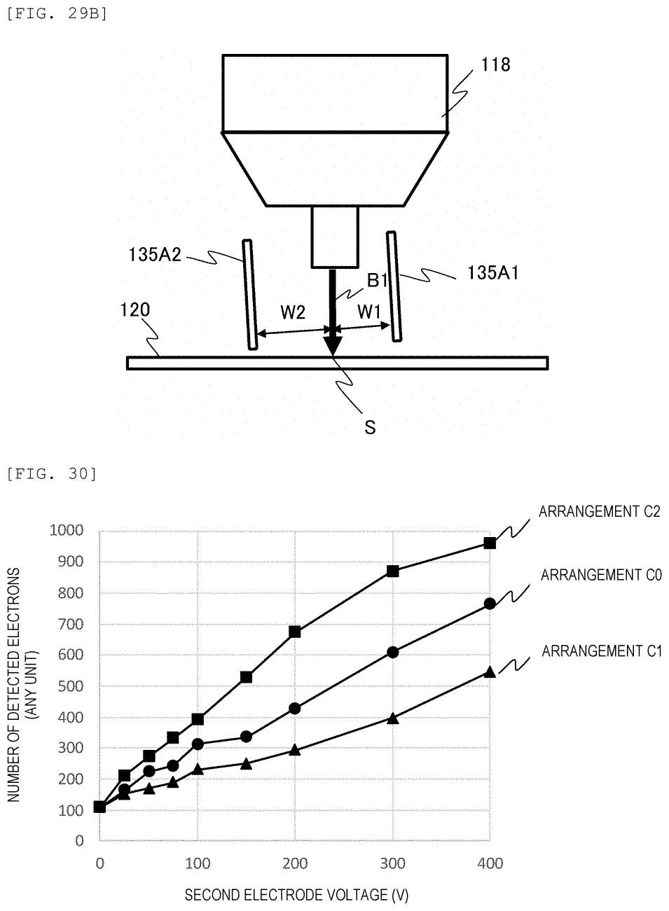

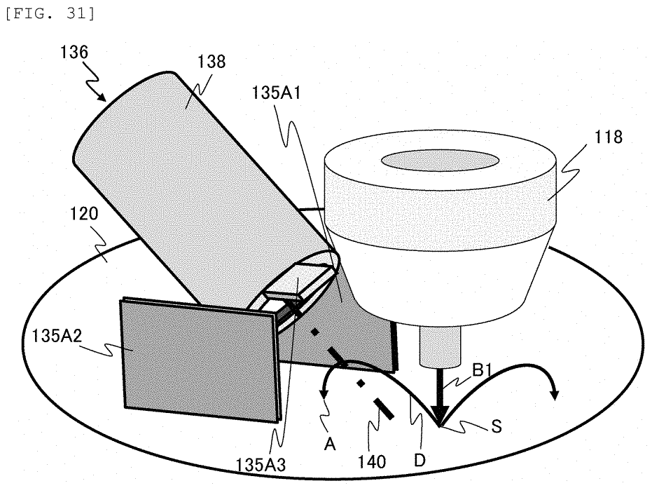

The 12th embodiment will be described with reference to FIGS. 28, 29A, 29B, and 30. FIG. 28 is a perspective view of the objective lens 118, the second detector 136, and the like as viewed obliquely from above, and FIGS. 29A and 29B are side views as viewed from a side facing the second detector 136. In addition, FIG. 30 shows an example of a result of obtaining, by electron trajectory analysis, a correlation between the voltage applied to the compensation electrode 135 and the number of the third electrons E detected by the second detector 136. FIG. 28 shows two trajectories of electrons among the low angle backscattered electrons D emitted from the point S in all directions. Further, FIG. 28 shows a trajectory in which the low angle backscattered electrons D emitted to the left side collide with the point A and the third electrons E emitted therefrom are incident on the second detector 136, and a trajectory in which the low angle backscattered electrons D emitted to the right side collide with the sample 120 and third electrons H emitted therefrom collide with the objective lens 118.

As in the first embodiment, the compensation electrode 135 includes the electrode 135A1 and the electrode 135A2 which are flat plates parallel to each other, and voltages having opposite polarities and equal absolute values are applied to the electrode 135A1 and the electrode 135A2. The compensation electrode 135 according to the 12th embodiment is attached to the cover 138 of the second detector 136 while being electrically insulated from the cover 138. By rotating the cover 138 about the center line 140 of the second detector 136 as a rotation axis, the electrode 135A1 and the electrode 135A2 are inclined with respect to the perpendicular line of the surface of the sample 120.

FIG. 29A shows a case where the cover 138 is rotated clockwise on a surface of the second detector 136 facing the fluorescent plate 137, and FIG. 29B shows a case where the cover 138 is rotated counterclockwise. In FIG. 29A, the electrode 135A1 is farther from the primary electron beam B1 than is the electrode 135A2, and W2<W1. In addition, in FIG. 29B, the electrode 135A1 is closer to the primary electron beam B1 than is the electrode 135A2, and W2>W1. Here, an arrangement of FIG. 29A is referred to as arrangement C1, an arrangement of FIG. 29B is referred to as arrangement C2, and a state where the electrode 135A1 and the electrode 135A2 are substantially perpendicular to the surface of the sample 120 is referred to as an arrangement C0. In the arrangement C0, a distance from the electrode 135A1 to the primary electron beam B1 is equal to a distance from the electrode 135A2 to the primary electron beam B1.

In FIG. 30, the number of detected electrons of the third electrons E is larger in the arrangement C2 than in the arrangement C1, and the number of detected electrons in the arrangement C0 is between the number of detected electrons in the arrangement C1 and the arrangement C2. In the arrangement C1 and the arrangement C2, the cover 138 is rotated by 10° in the respective directions. As described in the ninth embodiment, the third electrons E have a trajectory approaching the electrode 135A1 applied with the negative voltage, and is likely to be affected by the negative voltage. Therefore, the number of detected electrons of the third electrons E can be increased by shortening the distance between the primary electron beam B1 and the electrode 135A1 applied with the negative voltage, and bringing the electrode 135A1 closer to the point S at which the low angle backscattered electrons D are emitted.

According to the 12th embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the number of detected electrons of the third electrons E is increased by bringing the electrode 135A1, applied with the negative voltage, closer to the point S at which the low angle backscattered electrons D are emitted, a brighter backscattered electron image can be obtained.

The place where the electrode 135A1 and the electrode 135A2 are attached is not limited to the cover 138, and may be attached to, for example, the objective lens 118. Since the objective lens 118 is disposed at a stable position in the electron microscope, by attaching the electrode 135A1 and the electrode 135A2 to the objective lens 118, it is possible to prevent a decrease in sensitivity of the second detector 136 caused by a positional deviation between the electrode 135A1 and the electrode 135A2.

In the tenth to 12th embodiments, the case where the number of detected electrons of the third electrons E is increased by providing the electrode 135A1 and the electrode 135A2 asymmetrically has been described. Before the electrode 135A1 and the electrode 135A2 are asymmetrically disposed, a movement amount of the primary electron beam B1 when a voltage is applied to each of the electrode 135A1 and the electrode 135A2 may be measured, and the electrode 135A1 and the electrode 135A2 may be disposed based on the measured movement amount.

### 13th Embodiment

In the first embodiment, the case where the compensation electrode 135 is implemented with two electrodes of the electrode 135A1 and the electrode 135A2 has been described. In a 13th embodiment, a case where a third electrode is disposed in addition to the electrode 135A1 and the electrode 135A2 will be described. Since some of the configurations and functions described in the first embodiment can be applied to the 13th embodiment, the same reference numerals are used for the same configurations and functions, and the description thereof will be omitted.

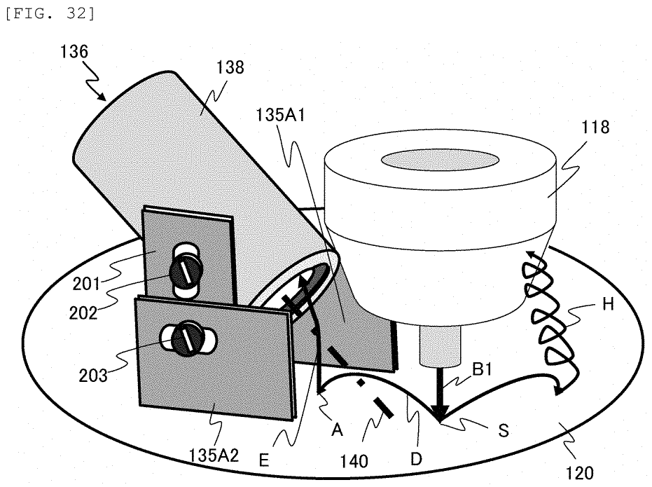

The 13th embodiment will be described with reference to FIG. 31. FIG. 31 is a perspective view of the objective lens 118, the second detector 136, and the like as viewed obliquely from above. FIG. 31 shows two trajectories of electrons among the low angle backscattered electrons D emitted from the point S in all directions. The low angle backscattered electrons D emitted to the left side of two trajectories collide with the point A and the emitted third electrons E are incident on the second detector 136. The low angle backscattered electrons D emitted to the right side collide with the sample 120 and the emitted third electrons H collide with the objective lens 118.

The compensation electrode 135 includes an electrode 135A3 together with the electrode 135A1 and the electrode 135A2 which are flat plates parallel to each other. The electrode 135A3 is disposed closer to the electron gun 101 than the electrode 135A1 and the electrode 135A2. Voltages having opposite polarities and equal absolute values are applied to the electrode 135A1 and the electrode 135A2, and a negative voltage is applied to the electrode 135A3. When a negative voltage is applied to the electrode 135A3 which is disposed closer to the electron gun 101 than the electrode 135A1 and the electrode 135A2, the third electrons E that are going to proceed closer to the electron gun 101 than the second detector 136 are pushed back and incident on the second detector 136. That is, by an electric field formed by the electrode 135A3 applied with the negative voltage, the number of the third electrons E detected by the second detector 136 increases.

According to the 13th embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, by disposing the electrode 135A3, applied with the negative voltage, closer to the electron gun 101 than the electrode 135A1 and the electrode 135A2, the number of detected electrons of the third electrons E increases, and therefore, a brighter backscattered electron image can be obtained.

### 14th Embodiment

In the 12th embodiment, the case where the electrode 135A1 and the electrode 135A2 are attached to the cover 138 of the second detector 136 while being electrically insulated from the cover 138 so as to be inclined with respect to the perpendicular line of the surface of the sample 120 has been described. In a 14th embodiment, a more specific method of attaching the electrode 135A1 and the electrode 135A2 will be described. Since some of the configurations and functions described in the first embodiment can be applied to the 14th embodiment, the same reference numerals are used for the same configurations and functions, and the description thereof will be omitted.

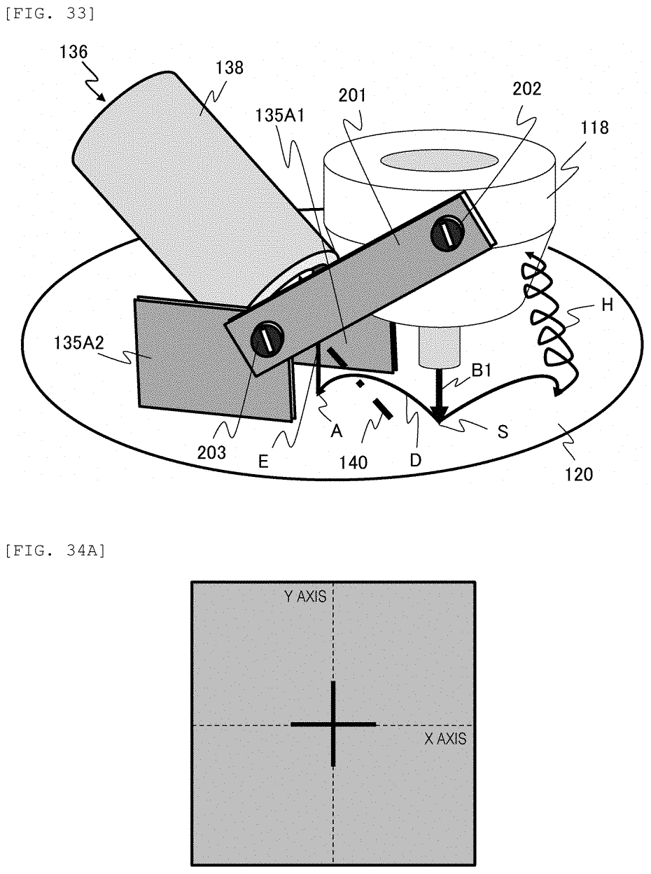

The 14th embodiment will be described with reference to FIGS. 32 and 33. FIGS. 32 and 33 are perspective views of the objective lens 118, the second detector 136, and the like as viewed obliquely from above. In addition, the operation of the 14th embodiment is the same as that of the 12th embodiment.

In FIG. 32, the electrode 135A1 and the electrode 135A2 are attached to the cover 138 of the second detector 136 via a position adjustment member 201. The position adjustment member 201 can be adjusted in position with respect to the cover 138, and is fixed by tightening a first screw 202. In addition, positions of the electrode 135A1 and the electrode 135A2 with respect to the position adjustment member 201 can be adjusted, and the electrode 135A1 and the electrode 135A2 are fixed by tightening a second screw 203. That is, the position adjustment member 201, the first screw 202, and the second screw 203 function as a mechanism that adjusts a position of the compensation electrode 135. When a fine movement function is added to the position adjustment member 201 or the electrode 135A1 and the electrode 135A2, the positions of the electrode 135A1 and the electrode 135A2 can be adjusted by external control.

As shown in FIG. 32, when the electrode 135A1 and the electrode 135A2 forming the compensation electrode 135 are attached to the cover 138 of the second detector 136, the second detector 136 and the compensation electrode 135 are integrated and can be handled as a detector unit. If the second detector 136 and the compensation electrode 135 can be handled as a detector unit, attachment to and detachment from the electron microscope are facilitated, and the maintenance cost can be reduced.

In FIG. 33, the electrode 135A1 and the electrode 135A2 are fixed to the objective lens 118 via the position adjustment member 201. The position adjustment member 201 can be adjusted in position with respect to the objective lens 118, and is fixed by tightening the first screw 202. In addition, the positions of the electrode 135A1 and the electrode 135A2 with respect to the position adjustment member 201 can be adjusted, and the electrode 135A1 and the electrode 135A2 are fixed by tightening the second screw 203. When a fine movement function is added to the position adjustment member 201 or the electrode 135A1 and the electrode 135A2, the positions of the electrode 135A1 and the electrode 135A2 can be adjusted by external control.

As shown in FIG. 33, when the electrode 135A1 and the electrode 135A2 forming the compensation electrode 135 are fixed to the objective lens 118 disposed at a stable position in the electron microscope, a positional deviation of the compensation electrode 135 can be reduced. As a result, it is possible to prevent a decrease in the sensitivity of the second detector 136 caused by the positional deviation of the compensation electrode 135.

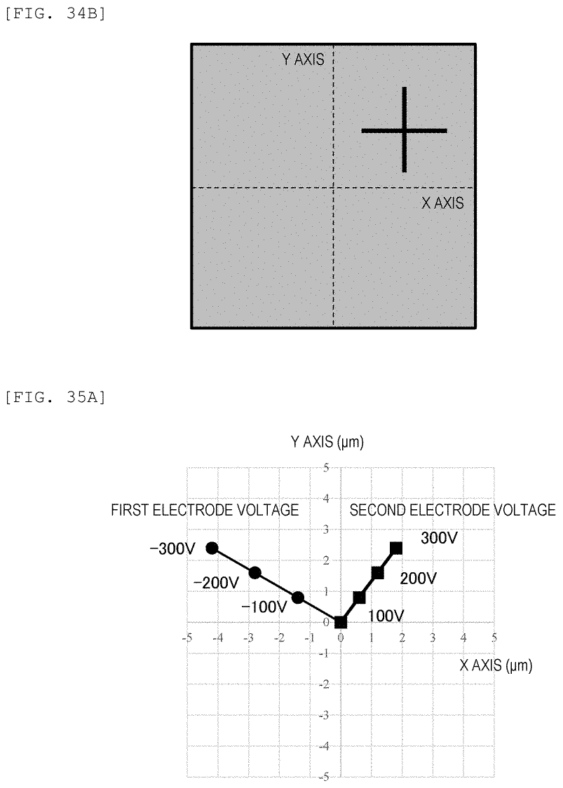

The measurement of the movement amount of the primary electron beam B1 when voltages are applied to the electrode 135A1 and the electrode 135A2 will be described with reference to FIGS. 34A and 34B. FIG. 34A is an observation image when a cross mark on the sample is observed without applying voltages to the electrode 135A1 and the electrode 135A2, and a position of the cross mark is adjusted to the center of the screen. FIG. 34B is an observation image when −100 V is applied to the electrode 135A1 at a sample position where the observation image of FIG. 34A is obtained, and the cross mark moves from the center of the screen to the upper right. The movement of the cross mark is caused by the application of the voltage to the electrode 135A1, and a movement amount of the cross mark corresponds to the movement amount of the primary electron beam B1. That is, the control device 150 functions as a mechanism that measures an electron beam movement amount, which is the movement amount of the primary electron beam B1, by comparing the observation images shown in FIG. 34A and FIG. 34B.

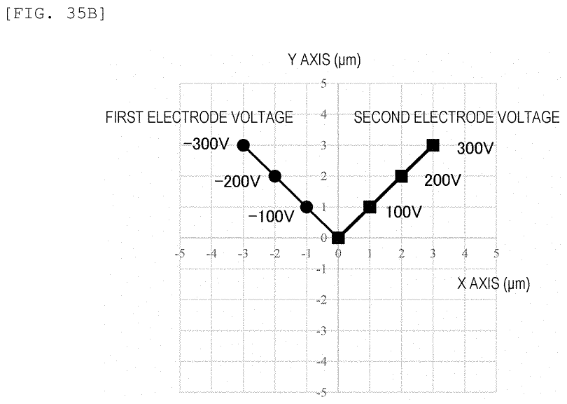

The adjustment of the positions of the electrode 135A1 and the electrode 135A2 based on the measured electron beam movement amount will be described with reference to FIGS. 35A and 35B. FIG. 35A shows electron beam movement amounts measured when −100 V, −200 V, and −300 V are applied to the electrode 135A1 and +100 V, +200 V, and +300 V are applied to the electrode 135A2. FIG. 35A shows that the electron beam movement amount is larger when the voltage is applied to the electrode 135A1 than when the voltage is applied to the electrode 135A2. Therefore, it can be seen that the electrode 135A1 and the electrode 135A2 are disposed asymmetrically with respect to the primary electron beam B1. A movement direction and a movement amount of the primary electron beam are obtained based on the position and the voltage of the compensation electrode 135. Here, the position of the compensation electrode 135 is adjusted using the position adjustment member 201, the first screw 202, and the second screw 203.

FIG. 35B shows the electron beam movement amount measured after the position of the compensation electrode 135 is adjusted using the position adjustment member 201, the first screw 202, and the second screw 203. FIG. 35B shows that the electron beam movement amount is substantially equal between when the voltage is applied to the electrode 135A1 and when the voltage is applied to the electrode 135A2. Therefore, it can be seen that the electrode 135A1 and the electrode 135A2 are disposed symmetrically with respect to the primary electron beam B1. The electrode 135A1 and the electrode 135A2 are not limited to be disposed symmetrically with respect to the primary electron beam B1, and may be disposed at desired positions using a mechanism that measures an electron beam movement amount and a mechanism that adjusts the position of the compensation electrode 135.

According to the 14th embodiment, similarly to the first embodiment, it is possible to provide an electron microscope capable of obtaining a scanning electron microscope image by backscattered electrons emitted at a low angle with respect to a sample surface, even for an electron microscope including an objective lens that leaks a magnetic field to a sample. In addition, since the position of the compensation electrode 135 is appropriately adjusted, a bright backscattered electron image can be stably obtained.

A plurality of embodiments of the electron microscope of the invention have been described above. The invention is not limited to the above embodiments, and can be embodied by modifying components without departing from a spirit of the invention. In addition, a plurality of components disclosed in the above embodiments may be appropriately combined. Further, some components may be deleted from all the components shown in the above embodiments.

### REFERENCE SIGNS LIST

100: electron microscope
101: electron gun
102: extraction electrode
104: anode
105: condenser lens
106: aperture
107: adjustment knob
108: upper deflector
109: lower deflector
110: first detector
111: electrode
112: electrode
113: coil
114: Wien filter
115: pull-up electrode
116: magnetic pole
117: objective lens coil
118: objective lens
119: gap
120: sample
121: sample stage
131: compensation magnetic pole
133: magnetic field
134: electric field
135: compensation electrode
136: second detector
137: fluorescent plate
138: cover
139: photo-multiplier tube
140: center line
150: control device
151: display
152: storage device
153: control table
154: secondary electron image
155: backscattered electron image
156: indicator
157: illumination direction
158: bright line
159: shadow
161: arrow
162: grid electrode
163: plate electrode
201: position adjustment member
202: first screw
203: second screw

1. An electron microscope for generating an observation image of a sample using an electron beam, the electron microscope comprising:
an electron source configured to irradiate the sample with the electron beam;
an objective lens configured to focus the electron beam by a leakage magnetic field which is a magnetic field leaked toward the sample,
a detector configured to detect a third electron which is an electron emitted when a low angle backscattered electron is caused to collide with the sample by the leakage magnetic field, the low angle backscattered electron being a backscattered electron emitted at a low angle with respect to a surface of the sample; and
a compensation electrode or a compensation magnetic pole provided between the sample and the detector and configured to control a trajectory of the third electron.

2. The electron microscope according to claim 1, wherein
the compensation electrode includes at least one compensation electrode having a shape bent toward a center line of the detector on a side closer to the objective lens.

3. The electron microscope according to claim 2, further comprising:
a grid electrode provided between the compensation electrode and the sample.

4. The electron microscope according to claim 1, wherein
the compensation electrode is configured to be applied with a voltage to form an electric field that prevents rotation of the low angle backscattered electron due to the leakage magnetic field.

5. The electron microscope according to claim 1, wherein
the observation image is generated based on a detection signal of a third electron emitted when a low angle backscattered electron emitted in a specific direction among all directions collides with the sample.

6. The electron microscope according to claim 1, wherein
the compensation magnetic pole is configured to form a magnetic field in a direction opposite to the leakage magnetic field.

7. The electron microscope according to claim 1, further comprising:
a shield electrode disposed between the electron beam and the compensation electrode to shield an electric field formed by the compensation electrode.

8. The electron microscope according to claim 7, wherein
at least a part of the shield electrode is a grid electrode.

9. The electron microscope according to claim 1, wherein
the compensation electrode includes two flat plates that are parallel to each other, substantially perpendicular to the surface of the sample, disposed at substantially the same distance from a center line of the detector, and configured to be applied with voltages having opposite polarities, where a negative voltage has an absolute value larger than an absolute value of a positive voltage.

10. The electron microscope according to claim 1, wherein
the compensation electrode includes two flat plates that are parallel to each other, disposed asymmetrically, and configured to be applied with voltages having opposite polarities and having equal absolute values.

11. The electron microscope according to claim 10, wherein
one of the two flat plates has a distance from a center line of the detector shorter than that of the other.

12. The electron microscope according to claim 10, wherein
one of the two flat plates has a distance from the electron beam shorter than that of the other.

13. The electron microscope according to claim 1, wherein
the compensation electrode is fixed to the objective lens.

14. The electron microscope according to claim 1, further comprising:
a mechanism configured to measure an electron beam movement amount when a voltage is applied to the compensation electrode; and
a mechanism configured to adjust a position of the compensation electrode.

15. The electron microscope according to claim 1, wherein
the compensation electrode includes two flat plates that are parallel to each other, substantially perpendicular to the surface of the sample, disposed at substantially the same distance from a center line of the detector, and configured to be applied with voltages having opposite polarities, and an electrode disposed closer to the electron source than are the two flat plates.
